(19) United States
(12) Patent Application Publication
(10) Pub. No.: US 2003/0188239 A1
(43) Pub. Date: Oct. 2, 2003

(54) Compacted test plan generation for integrated circuit testing, test sequence generation, and test

(76) Inventors: Toshinori Hosokawa, Tokyo (JP); Hiroshi Date, Fukuoka-shi (JP); Michiaki Muraoka, Ikoma-gun (JP)

Correspondence Address: CHRISTIE, PARKER & HALE, LLP, P.O. BOX 7068, PASADENA, CA, 91109-7068, US

(21) Appl. No.: 10/208,110

(22) Filed: Jul. 29, 2002

(30) Foreign Application Priority Data
Nov. 21, 2001 (JP) 2001-356511

(51) Int. Cl. G01R 31/28

(52) U.S. Cl. 714/724

(57) ABSTRACT

In a strongly testable DFT method, the length of a test sequence is reduced, thereby reducing the amount of circuitry to be added for testing purposes. Test plans, generated one for each of circuit elements forming a data path, are scheduled in parallel in a form that can be compacted, and a compaction operation is applied to generate a compacted test plan. The test sequence is generated by inserting the test patterns needed for each circuit element into the compacted test plan.

### BACKGROUND OF THE INVENTION

1. Field of the Invention

The present invention relates to a method for generating a compacted test plan for testing an integrated circuit, a method for generating a test sequence, a method for testing, apparatuses for implementing the methods, and programs for implementing the methods.

2. Description of the Related Art

In recent years, with increasing amounts of circuitry mounted on LSIs, LSI testing has become increasingly important, and to address this trend, automation of LSI test design is an essential requirement. For the automation of LSI test design, high fault efficiency must be achieved, and Design for Testability (DFT) is required for that purpose. Scan design is a DFT technique most widely used for LSI testing, but this technique has the following problems.

(1) As a change is made to the circuit after logic synthesis, restrictions at the time of synthesis, such as timing, are compromised.

(2) The test sequence is long.

(3) It is difficult to perform at-speed testing.

To solve the above problems, DFT methods that apply DFT to RTL design circuits before logic synthesis have been proposed. Generally, an RTL design circuit comprises two parts, a data path for processing data and a controller for controlling the operation of the data path. Signals transferred from the data path to the controller are called status signals, and signals from the controller to the data path are called control signals. In this specification, a description will be given focusing mainly on RTL data path circuits. First, since DFT is applied to the RTL circuit, application of DFT to the circuit after logic synthesis is not needed, which solves the problem (1). As a DFT method aimed at solving the problems (2) and (3), there is proposed a design-for-strong-testability method in which a test pattern is propagated from an external input to an input of a circuit element under test via a data transfer line usually used by the data path and a response output from the circuit element is propagated to an external output (Wada et al., “A non-scan DFT method for data paths that achieves complete fault efficiency,” IEICE Technical Report, J82-D-I, pp. 843-851, July 1999).

According to the above literature, the data path circuit is strongly testable if the following two conditions can be satisfied for every circuit element: 1) any arbitrary value can be propagated from the external input to its input terminal (strong controllability), and 2) the arbitrary value that its output terminal can take can be propagated to the external output (strong observability). If the data path circuit is strongly testable, since there exists a test plan for every circuit element, a hierarchical test that achieves complete fault efficiency becomes possible by using a set of test patterns having complete fault efficiency for each circuit element. Here, the circuit elements include combinational modules and registers and, in many cases, the hierarchical test is applied to the combinational modules.

In the method described in the above literature, as the combinational modules in the strongly testable data path circuit are individually and sequentially subjected to the test, the test sequence length L for the strongly testable data path circuit is expressed by equation (1) below.

$$L = {{\sum }^{n}}_{j = 1} ( {L}_{i} \times {N}_{j} ) \qquad ( 1 )$$

where n is the number of combinational modules in the circuit, Lⱼ (j=1, 2, . . . , n) is the test plan length for each combinational module, and Nⱼ (j=1, 2, . . . , n) is the number of test patterns for each combinational module.

As can be seen from equation (1), the test sequence length for the strongly testable data path circuit rapidly increases as the number of combinational modules or the amount of circuitry of each combinational module increases.

### SUMMARY OF THE INVENTION

It is accordingly an object of the present invention to reduce the entire test sequence length for a data path, thereby reducing the amount of circuitry required for testing as well as the time required to carry out the testing.

In this specification, there is proposed a test generation method for a strongly testable data path circuit that uses a compacted test plan table (or a compacted test plan) generated by scheduling test plans for the respective combinational modules and compacting them in order to shorten the test sequence length for the strongly testable data path circuit by carrying out tests in parallel fashion on as many combinational modules as possible. There is also proposed a heuristic algorithm for generating a compacted test plan having the shortest length.

A compacted test plan generation method according to the present invention comprises the steps of: generating a plurality of test plans, one for each of a plurality of circuit elements contained in an RTL data path circuit; and compacting the generated plurality of test plans and thereby generating a compacted test plan.

Preferably, the test plan compacting step includes the substeps of: (a) selecting and extracting one first test plan from a set of test plans; (b) further selecting and extracting zero or more second test plans from the set of test plans after the substep (a); (c) compacting the first and second test plans and thereby generating a partly compacted test plan; (d) repeating the substeps (a) to (c) until the set of test plans becomes an empty set; and (e) taking a set of the generated partly compacted test plans as a new set of test plans, and repeating the substeps (a) to (d) until the number of partly compacted test plans becomes 1.

Preferably, the test plan compacting step further includes the substeps of: (f) repeating the substeps (a) to (e) a prescribed number of times by changing an initial condition; and (g) adopting a compacted test plan having the shortest length from among the compacted test plans obtained by performing the repeating substep (f).

Alternatively, the test plan compacting step may include the substeps of: (a) selecting from among the plurality of test plans a pair of test plans that, when compacted, would yield a partly compacted test plan having the shortest length; (b) compacting the selected pair of test plans and thereby generating a partly compacted test plan; (c) selecting from among the test plans remaining uncompacted a test plan that, when compacted with the partly compacted test plan, would yield a partly compacted test plan having the shortest length; (d) compacting the selected test plan with the partly compacted test plan and thereby generating a partly compacted test plan; and (e) repeating the substeps (c) and (d) until there is no test plan remaining uncompacted.

A test sequence generation method according to the present invention comprises the steps of: generating a compacted test plan by the above-described method; generating a necessary number of test patterns for each of the plurality of circuit elements contained in the RTL data path circuit; and generating a test sequence by inserting the test patterns into the compacted test plan.

A test method according to the present invention sequentially supplies the test sequence generated by the above-described method to the data path circuit.

### BRIEF DESCRIPTION OF THE DRAWINGS

FIG. 1 is a diagram showing the configuration of a circuit before conversion to the gate level;

FIG. 2 is a diagram showing a data path in a GCD circuit as one example of a circuit described at the RTL level;

FIG. 3 is a diagram showing the data path in the GCD circuit with DFT;

FIG. 4 is a diagram showing a DFT process;

FIG. 5 is a diagram showing a test sequence generation process;

FIG. 6 is a diagram showing a compacted test plan generation process;

FIG. 7 is a flowchart illustrating a first heuristic algorithm for compacted test plan generation;

FIG. 8 is a diagram showing one example of a test plan compactibility graph;

FIG. 9 is a flowchart illustrating a second heuristic algorithm for compacted test plan generation;

FIG. 10 is a diagram showing a test sequence generation process;

FIG. 11 is a flowchart illustrating the details of the test sequence generation process;

FIG. 12 is a diagram showing a test controller according to the prior art;

FIG. 13 is a diagram showing the details of the test controller of FIG. 12;

FIG. 14 is a state transition diagram for a sequential circuit TPG shown in FIG. 13;

FIG. 15 is a diagram showing the details of a test controller according to the present invention;

FIG. 16 is a state transition diagram for a sequential circuit TPG shown in FIG. 15;

FIG. 17 is a diagram showing the generation of a compacted test plan from grouped test plans;

FIG. 18 is a flowchart illustrating a test plan grouping process;

FIG. 19 is a diagram for explaining a decreasing point;

FIG. 20 is a diagram showing the details of the test controller when the grouping process is introduced;

FIG. 21 is a state transition diagram for a sequential circuit TPG shown in FIG. 20;

FIG. 22 is a circuit block diagram showing one example of a hierarchically structured circuit;

FIG. 23 is a circuit block diagram showing the circuit of FIG. 22 to which a DFT is applied; and

FIG. 24 is a circuit block diagram showing a test controller for the hierarchically structured circuit.

### DESCRIPTION OF THE PREFERRED EMBODIMENTS

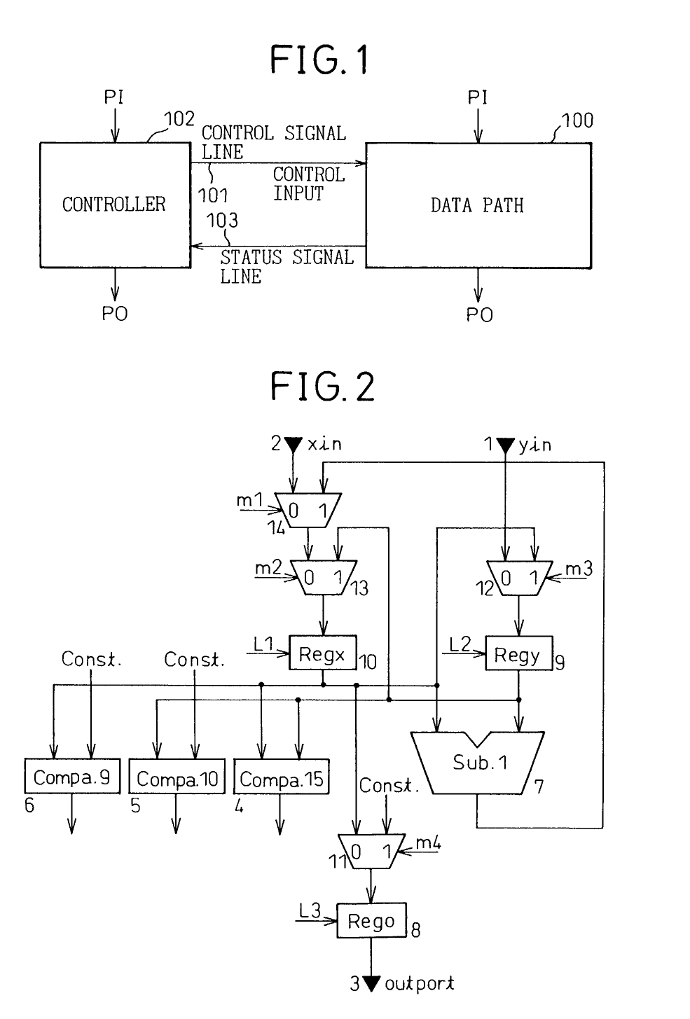

A circuit before conversion to the gate level comprises, as shown in FIG. 1, a data path 100 for processing data and a controller 102 for controlling the operation of the data path 100, and the data path 100 is described at the register transfer level (hereinafter RTL).

FIG. 2 shows a data path in a circuit for computing a greatest common divisor (GCD), as one example of the data path described at RTL. In FIG. 2, circuit elements 1 and 2 are external inputs xin and yin, circuit element 3 is an external output, circuit elements 4 to 6 are comparators, circuit element 7 is a subtractor, circuit elements 8 to 10 are registers, and circuit elements 11 to 14 are multiplexers (or selectors). The external inputs xin and yin each correspond to PI in FIG. 1, the external output corresponds to PO, L1 to L3 and m1 to m4 each correspond to a control input (signal line) 101, and the output of each of the comparators 4 to 6 corresponds to a status signal line 103.

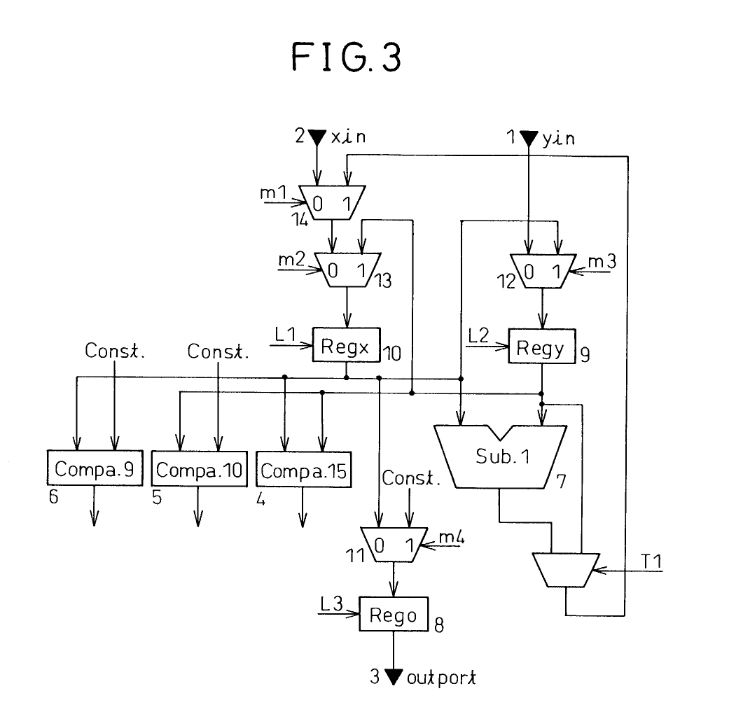

The data path circuit of FIG. 2 becomes strongly testable (designed for testability) when a multiplexer is added for passing the value at the right-hand side input of the circuit element 7 through to the output side, as shown in FIG. 3. The control input to this multiplexer for testing is designated by T1. Test plans for the respective circuit elements (combinational modules only) in the data path circuit with DFT of FIG. 3 are shown in table 1. In Table 1, b indicates a single-bit or multi-bit value, and X means don't care.

TABLE 1

| | | | | | | | | | | |
|---|---|---|---|---|---|---|---|---|---|---|
| TIME | xin | yin | L1 | L2 | L3 | m1 | m2 | m3 | m4 | T1 |

CIRCUIT ELEMENT 11

| | | | | | | | | | | |
|---|---|---|---|---|---|---|---|---|---|---|
| 0 | b | x | 1 | x | x | 0 | 0 | x | x | x |
| 1 | x | x | x | x | 1 | x | x | x | b | x |
| 2 | x | x | x | x | x | x | x | x | x | x |

CIRCUIT ELEMENT 12

| | | | | | | | | | | |
|---|---|---|---|---|---|---|---|---|---|---|
| 0 | b | x | 1 | x | x | 0 | 0 | x | x | x |
| 1 | x | b | x | 1 | x | x | x | b | x | x |
| 2 | x | x | 1 | x | x | 1 | 0 | x | x | 1 |
| 3 | x | x | x | x | 1 | x | x | x | 0 | x |
| 4 | x | x | x | x | x | x | x | x | x | x |

CIRCUIT ELEMENT 13

| | | | | | | | | | | |
|---|---|---|---|---|---|---|---|---|---|---|
| 0 | x | b | x | 1 | x | x | x | 0 | x | x |
| 1 | b | x | 1 | x | x | 0 | b | x | x | x |
| 2 | x | x | x | x | 1 | x | x | x | 0 | x |
| 3 | x | x | x | x | x | x | x | x | x | x |

CIRCUIT ELEMENT 14

| | | | | | | | | | | |
|---|---|---|---|---|---|---|---|---|---|---|
| 0 | x | b | x | 1 | x | x | x | 0 | x | x |
| 1 | b | x | 1 | x | x | b | 0 | x | x | 1 |
| 2 | x | x | x | x | 1 | x | x | x | 0 | x |
| 3 | x | x | x | x | x | x | x | x | x | x |

CIRCUIT ELEMENT 7

| | | | | | | | | | | |
|---|---|---|---|---|---|---|---|---|---|---|
| 0 | b | b | 1 | 1 | x | 0 | 0 | 0 | x | x |
| 1 | x | x | 1 | x | x | 1 | 0 | x | x | b |
| 2 | x | x | x | x | 1 | x | x | x | 0 | x |
| 3 | x | x | x | x | x | x | x | x | x | x |

CIRCUIT ELEMENT 6

| | | | | | | | | | | |
|---|---|---|---|---|---|---|---|---|---|---|
| 0 | b | x | 1 | x | x | 0 | 0 | x | x | x |
| 1 | x | x | x | x | x | x | x | x | x | x |

CIRCUIT ELEMENT 5

| | | | | | | | | | | |
|---|---|---|---|---|---|---|---|---|---|---|
| 0 | x | b | x | 1 | x | x | x | 0 | x | x |
| 1 | x | x | x | x | x | x | x | x | x | x |

CIRCUIT ELEMENT 4

| | | | | | | | | | | |
|---|---|---|---|---|---|---|---|---|---|---|
| 0 | b | b | 1 | 1 | x | 0 | 0 | 0 | x | x |
| 1 | x | x | x | x | x | x | x | x | x | x |

A test plan is a time sequence of external inputs for propagating a value from an external input to an input of a particular circuit element and propagating the output value of that circuit element to the external output. Taking the test plan for the circuit element 13 as an example, at time 0, a test input value is applied to the external input yin and, since m3 is 0 and L2 is 1, the value is loaded into the circuit element 9, a register, and is applied to the “1” side input of the circuit element 13 which is a selector. At time 1, another test input value is applied to the external input xin and, since m1 is 0, the value is applied to the “0” side input of the selector 13. If there is no fault in the selector 13 and its vicinity, one of the input values is selected for output according to the value 0 or 1 applied to m2, and since L1 is 1, the output value is loaded into the circuit element 10 which is a register. At time 2, as m4 is 0 and L3 is 1, the test result is loaded into the circuit element 8, a register, and is output to the outside.

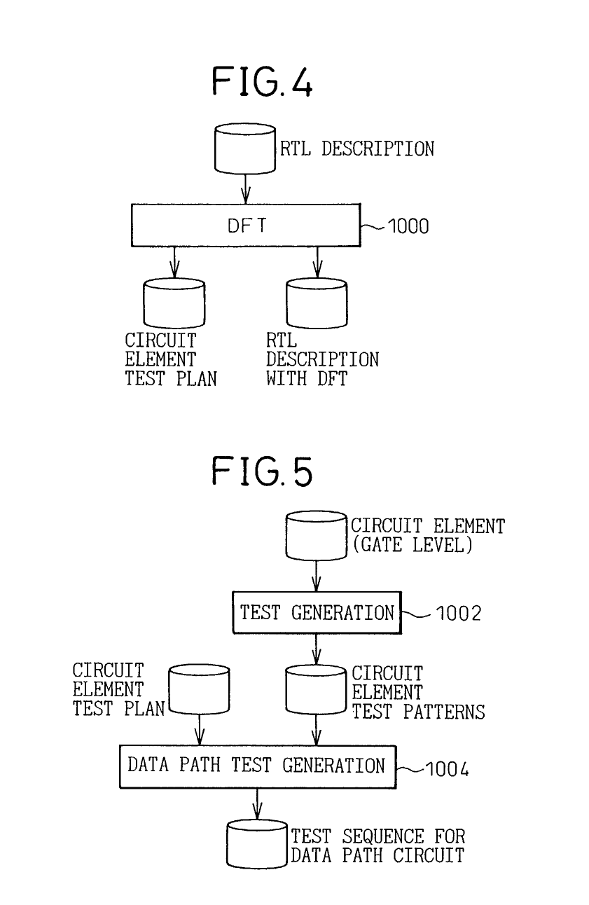

As shown in FIG. 4, the test plans are generated at the same time that a DFT (for example, the addition of the selector shown in FIG. 3) is applied for conversion from the RTL description to the RTL description with DFT (step 1000). Then, as shown in FIG. 5, test patterns (specific values of b in the test plan) for detecting, for example, single stuck-at faults in the gate level circuit after logic synthesis are generated for each circuit element (combinational module) (step 1002) and, according to the prior art, the test sequence for the data path circuit is generated by inserting the test patterns into the test plan for each circuit element (step 1004).

In the present invention, on the other hand, before inserting the test patterns into the test plan for each circuit element, a compacted test plan is generated by compacting a plurality of test plans, and the test sequence is generated by replacing b's in the compacted test plan with the test patterns.

This will be explained by taking as an example the case in which a compacted test plan is generated by compacting two test plans shown in Table 2.

TABLE 2

| | | | | | |
|---|---|---|---|---|---|
| Time | Pl₀ | Pl₁ | Pl₂ | Pl₃ | Pl₄ |

(a)

| | | | | | |
|---|---|---|---|---|---|
| 0 | X | b | 0 | 1 | X |
| 1 | X | 0 | 1 | X | X |
| 2 | X | X | X | X | X |

(b)

| | | | | | |
|---|---|---|---|---|---|
| 0 | X | b | 0 | 1 | X |
| 1 | X | 0 | 1 | X | X |
| 2 | X | X | X | X | X |

The compaction operation ∩_{f} for generating the compacted test plan is shown in Table 3.

TABLE 3

| | | | | |
|---|---|---|---|---|
| ∩_{f} | b | X | 0 | 1 |
| b | φ | b | φ | φ |
| X | b | X | 0 | 1 |
| 0 | φ | 0 | 0 | φ |
| 1 | φ | 1 | φ | 1 |

In Table 3, φ in the calculation result indicates that it is incompactible.

When the second test plan is scheduled relative to the first test plan so that the second test plan starts at time k in the first test plan, if there is no φ in the result of the compaction operation for each input at any of the times where the two test plans overlap, the second test plan can be compacted with the first test plan with a skew k. In the example shown in Table 2, the test plan (b) can be compacted with the test plan (a) with a skew 2as shown in equation (2) below and, as a result, the compacted test plan shown on the right-hand side of equation (2) is generated.

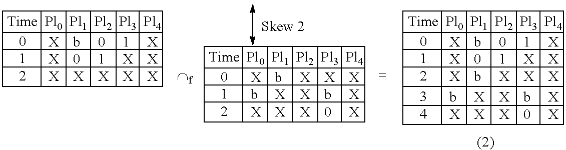

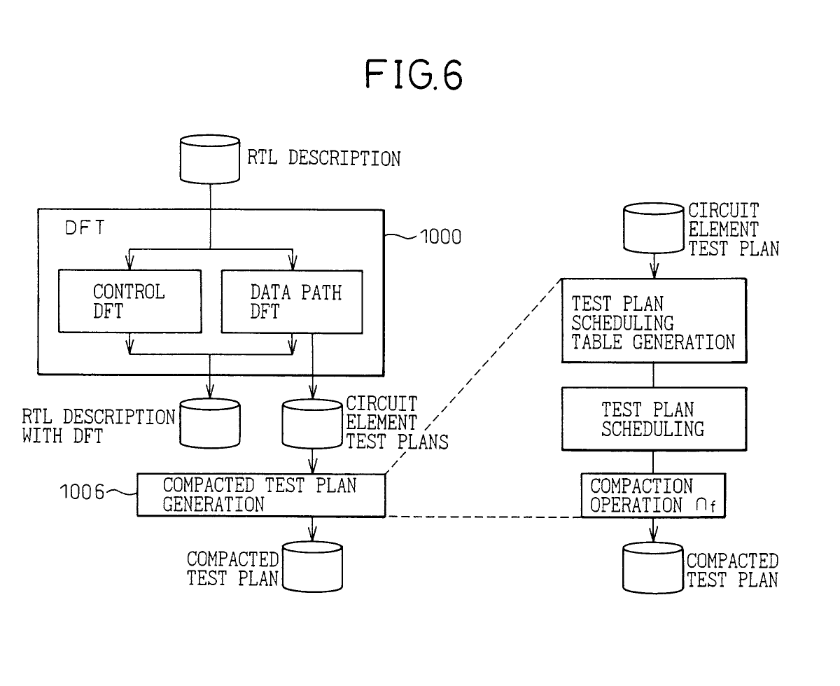

More specifically, according to the present invention, from the test plans generated for the respective circuit elements in the data path by applying a DFT to the RTL description (step 1000), a compacted test plan is generated (step 1006), as shown in FIG. 6, and the test sequence is generated by using the compacted test plan, rather than using the test plans generated as shown in FIG. 5 for the respective circuit elements.

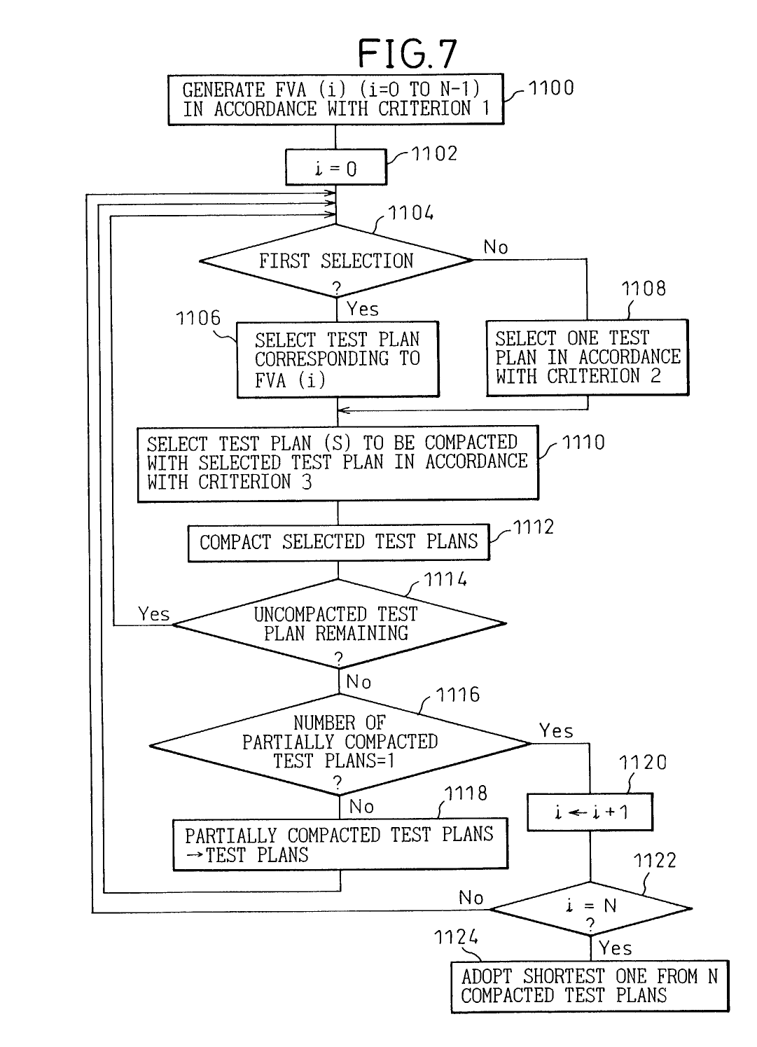

Usually, there is more than one possible sequence in which the compaction is performed; therefore, the compaction should be performed in the sequence that will result in the generation of a compacted test plan having the shortest test plan length. However, when the number of test plans involved is large, it is not easy to find the compaction sequence that provides the compacted test plan of the shortest length. FIG. 7 shows a first heuristic algorithm for performing the test plan compaction in the sequence that will result in the generation of a compacted test plan considered to have the shortest length.

In FIG. 7, first an array FVA (i) is generated (step 1100). As will be described in detail later, the FVA (i) is generated by sorting a set of elements at all times in all test plans in accordance with a criterion 1 (to be described later). After setting i=0 (step 1102), when a selection is made for the first time from among the plurality of test plans before compaction, the test plan corresponding to the FVA (i) is selected (step 1106); otherwise, one test plan is selected in accordance with a criterion 2 (step 1108). Next, a test plan or text plans to be compacted with the selected test plan is selected in accordance with a criterion 3 (step 1110), and the selected test plans are compacted to generate a partly compacted test plan (step 1112).

The process from step 1104 to step 1112 is repeated until there is no test plan remaining uncompacted (step 1114); when this process is completed, if the number of partly compacted test plans generated is 2 or larger, the set of partly compacted test plans is taken as a set of test plans (step 1118), and the process from step 1104 to step 1116 is repeated.

When the number of partly compacted test plans becomes 1, i is incremented (step 1120), and if i is not N (step 1122), the process from step 1104 to step 1120 is repeated.

Of the N compacted test plans thus obtained, the compacted test plan with the shortest length is adopted (step 1124).

In the above flow, in step 1116, the number of partly compacted test plans might never decrease to 1. Considering this, if, in step 1116, the number of partly compacted test plans is the same as the result of the previous cycle of process, this will be treated as an exception, and the plurality of partly compacted test plans are concatenated to form a compacted test plan, after which the process proceeds to step 1120.

Before explaining the above-mentioned FVA (i) and criteria 1 to 3, a test plan compactibility graph will be explained first.

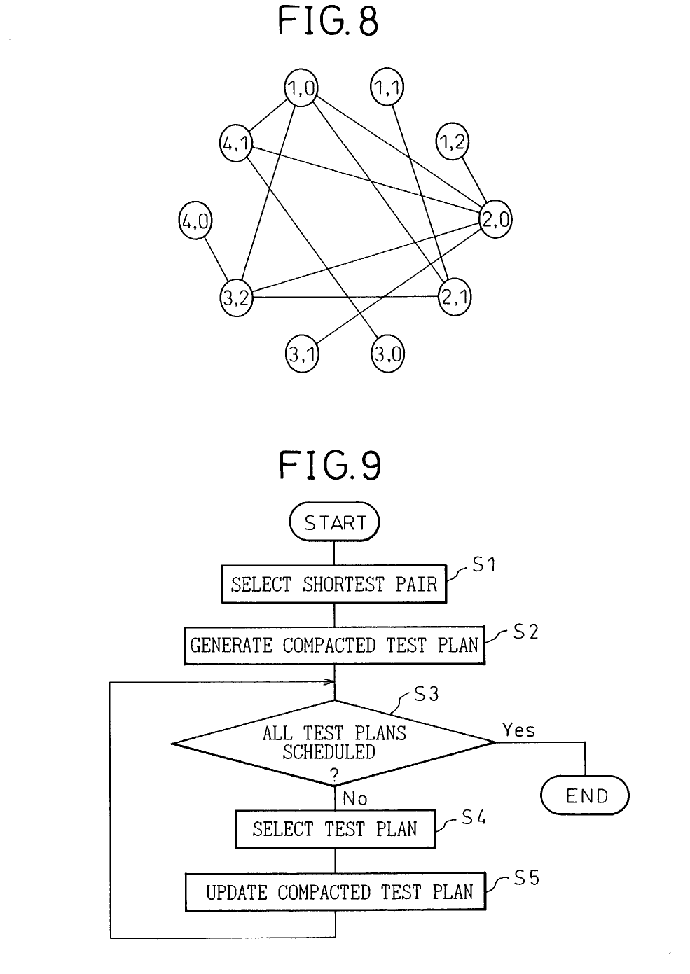

When four test plans T₁ to T₄ are provided as shown in Table 4, a test plan compactibility graph such as shown in FIG. 8 is generated for the four test plans.

TABLE 4

| | | | | | |
|---|---|---|---|---|---|
| Time | P₀ | P₁ | P₂ | P₃ | P₄ |

(a) T₁

| | | | | | |
|---|---|---|---|---|---|
| 0 | X | b | X | X | X |
| 1 | b | X | X | b | X |
| 2 | X | X | X | 0 | X |

(b) T₂

| | | | | | |
|---|---|---|---|---|---|
| 0 | b | X | X | X | X |
| 1 | X | X | b | X | 0 |

(c) T₃

| | | | | | |
|---|---|---|---|---|---|
| 0 | X | b | 0 | 1 | X |
| 1 | X | 0 | 1 | X | X |
| 2 | X | X | X | X | X |

(d) T₄

| | | | | | |
|---|---|---|---|---|---|
| 0 | b | 0 | 0 | 1 | X |
| 1 | X | X | X | X | X |

Label (i, j) assigned to each vertex of the test plan compactibility graph means time j in test plan i, and an edge between a vertex (i, j) and a vertex (k, m) means that the test plan k can be compacted with the test plan i with a skew j-m (≧0). In the example of FIG. 8, the presence of an edge between the vertices (2, 0) and (1, 0) and between the vertices (2, 1) and (1, 1) indicates that the test plan T₁ can be compacted with the test plan T₂ with a skew 0. The presence of an edge between the vertices (2, 1) and (1, 0) indicates that the test plan T₁ can also be compacted with the test plan T₂ with a skew 1. Conversely, the edge between the vertices (1, 2) and (2, 0) indicates that the test plan T₂ can be compacted with the test plan T₁ with a skew 2.

In the compactibility graph of FIG. 8, there exists a clique consisting, for example, of vertices (1, 0), (2, 1), and (3, 2); this means that when the test plans T₁ and T₂ are compacted with the test plan T₃ with skews 2 and 1, respectively, the test plans can be compacted in such a manner as to have an overlap portion common to all the three test plans, as shown in equation (3) below.

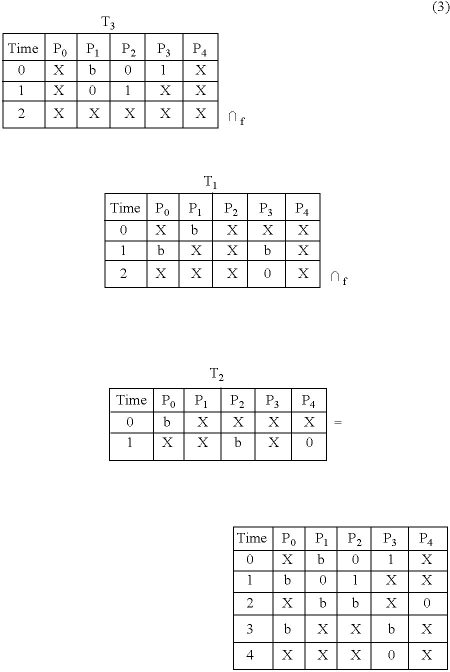

In the first heuristic algorithm of the present invention, maximum cliques are sequentially extracted from the compactibility graph in accordance with prescribed criteria. Extracting maximum cliques corresponds to generating partly compacted test plans by compacting test plans (steps 1104 to 1114 in FIG. 7). When the number of partly compacted test plans is 2 or larger, a compactibility graph is generated once again by taking the set of partly compacted test plans as a set of compacted test plans, and the above process is repeated.

Then, N compacted test plans are generated by changing the vertex that is first put in a clique when the clique is extracted for the first time from the partly compactibility graph (steps 1120 and 1122 in FIG. 7), and the shortest of the N compacted test plans is adopted (step 1124). The array FVA (step 1100 in FIG. 7) is an array that indicates the priority of the vertex to be extracted first, and the FVA is generated by sorting the vertices of the test plan compactibility graph in accordance with the following factors.

(Sort factor 1) All the vertices are sorted in decreasing order of Σnbr(u), where u is an element in nbr(v) which denotes a set of adjacent vertices of each vertex v.

(Sort factor 2) Vertices v whose value of Σnbr(u) is the same are sorted in decreasing order of nbr(v).

(Sort factor 3) Vertices v whose value of nbr(v) is the same are sorted in increasing order of Σw(v, u) (u ∈ nbr(v)).

The details of the first heuristic algorithm of the present invention are shown in Table 5 using a pseudo-C language, and the functions used therein are shown in Table 6.

TABLE 5
Gen_CTPT(T, N) /*Generate a compacted test plan table */
{

Generate a first vertex array FVA;
for (i = 0; i < N; i++) {

CT = T;
do {

SC = φ
while (CT != φ) {

generate a test plan compatibility graph G from CT;
if (CT == T) {

C = Extract_first_clique(G, FVA[i]);

}
else {

C = Extract_clique(G);

}
ST = Schedule_test_plan(C);
SC = SC ∪ {ST};
CT = CT-C;

}
CT = SC;

} while (|SC| > 1);
if (i == 0) {

Min_CTPT = ST;

}
else if (|ST| < |Min_CTPT|){
Min_CTPT = ST;
}

}
return Min_CTPT;

}

TABLE 6
Extract_clique(G)
{

C = Best_first_vertex(G);
while ((S = Candidates(C)) != φ) {

v = Best_vertex (S,C);
C = C ∪ {v};

}
return C;

}
Best_first_vertex(G)
{

V1 = {v| Σ|nbr(u) | is maximum in V, u ∈ nbr(v)};
V2 = {v| |nbr(v) | is maximum in V1);
V3 = {v| Σw1 (u,v) is minimum in V2, u ∈ nbr(v)};
C = {v| j(v) is minimum in V3);
return C;

}
Candidates(C)
{

S = {v| v ∈ V − C Λ ∀ u ∈ C, ∃ (u,v) ∈ E};
return S;

}
Best_vertex(S,C)
{

V4 = {v| |nbr(v) | is maximum in S, nbr(v) ∈ S};
V5 = {v| |ctp(v,C) | is minimum in V4};
V6 = {v| X(ctp(v,C)) is maximum in V5};
v = j(v) is minimum in V6;
return v;

}
Extract_first_clique(G,FVA[i]}
{

C = FVA[1];
while ((S = Candidates(C)) != φ) {

v = Best_vertex(S,C);
C = C ∪ {v};

}
return C;

}

In Table 5, FVA (i) is generated on line 3, and by sequentially substituting values 0 to N-1 for i on line 4, the processing from line 6 to 21 (described in detail below) is repeated. Of the compacted test plans generated for the respective values of i, the shortest one is adopted as Min_CTPT on lines 22 to 28.

In the processing from line 6 to 21, first a set SC of partly compacted test plans obtained by compacting several test plans is initialized to an empty set (line 7). Next, the following processing is repeated until the test plan set CT becomes an empty set (line 8).

First, a test plan compactibility graph G=(V, E, j, t) is generated from T (line 9).

One maximum clique is extracted from the test plan compactibility graph G by using the function Extract_first_clique( ) or Extract_clique( ) (to be described later) (lines 10 to 15).

Next, using the function Schedule_test_plan( ), each test plan as an element of the clique C is scheduled on an appropriate time in a test plan compaction scheduling table in accordance with scheduling information, and a partly compacted test plan ST is generated (line 16).

ST is added to the partly compacted test plan set SC (line 17).

Next, the test plans, the elements of the clique C, are deleted from the test plan set T (line 18).

When CT becomes an empty set, the above processing loop (lines 8 to 19) is exited, the partly compacted test plan set SC is taken as a new CT (line 20), and the processing from line 6 to 21 is repeated until the number of elements in the partly compacted test plan set decreases to 1. That is, every partly compacted test plan generated here is considered to be a new test plan. When there remains only one element in the partly compacted test plan set, that remaining element ST provides a compacted test plan for each value of i.

In the processing on lines 10 to 15, when CT is equal to T, that is, when extracting the first clique from the graph G, Extract_first_clique( ) is used; otherwise, Extract_clique( ) is used. The difference between the two is that in the former case, the vertex that is first put in the clique to be extracted is FVA (i), while in the latter case, the vertex is determined by the function Best_first_vertex( ). The function Best_first_vertex( ) determines the vertex in accordance with the following criterion. This criterion corresponds to the criterion 2 used in step 1108 in FIG. 7.

(H1) The vertex for which the sum Σ|nbr(u)|, i.e., the sum of adjacent vertices of all the vertices u contained in the adjacent vertex set nbr(v) of vertex v, is the largest, is selected (vertex set V1, line 12 in Table 6).

By selecting the vertex for which the sum of adjacent vertices for adjacent vertices is the largest, the number of vertices that have the chance of being added to C increases and, as a result, the probability of extracting the maximum clique increases.

(H2) In the vertex set V1, the vertex having the largest number of adjacent vertices is selected (vertex set V2, line 13).

By adding the vertex having the largest number of adjacent vertices to C, the probability of extracting the maximum clique increases, as in (H1).

(H3) In the vertex set V2, the vertex for which the sum of the weights v1 (u, v) assigned to the sides (u, v) lying between the vertex v and all the vertices u contained in the adjacent vertex set nbr(v) of the vertex v is the smallest, is selected (vertex set V3, line 14).

By selecting the vertex for which the sum of the weights is the smallest, the probability of extracting the maximum clique increases, as in (H1).

If there is more than one vertex in V3, then to determine one vertex the vertex that has the smallest module number is selected and inserted in C (line 15), and C is returned (line 16).

When one vertex is thus determined, the product set of the adjacent vertex sets for the vertices u contained in the clique set C is obtained using the function Candidates( ), and is set as new S (line 4 or 34). S is searched (line 4 or 34), and one vertex v is selected from S (line 5 or 35) and inserted in C (line 6 or 36); this process is repeated until S becomes an empty set. When S becomes an empty set, C is returned. When selecting “one vertex v from S”, the following three heuristics are used for each vertex in the candidate vertex set S (function Best_vertexo( )). This corresponds to the criterion 3 in FIG. 7.

H1′: Select the vertex for which the number of adjacent vertices is the largest.

In the vertex set S, the vertex for which the number of adjacent vertices of vertex v in S is the largest is selected (vertex set V4).

This serves to increase the probability of extracting the maximum clique.

H2′: Select the vertex that, after the compaction operation, would provide the shortest test plan length.

In the vertex set V4, the vertex is selected that provides the shortest test plan length when the test plan is generated by performing the compacting operation on the vertex v and all the vertices contained in C (vertex set V5).

This serves to increase the probability of minimizing the test plan length when the test plan is generated by performing the compaction operation on the elements of the clique after extracting the clique.

H3′: Select the vertex for which the number of X's (or the proportion of X's) contained in the test plan after the compaction operation is the largest (highest).

In the vertex set V5, the vertex is selected that maximizes the number of X's (or the proportion of X's) contained in the test plan when the test plan is generated by performing the compacting operation on the vertex v and all the vertices contained in C (vertex set V6). This increases the number of X's (or the proportion of X's) contained in the test plan generated by extracting the clique and performing the compaction operation on the elements of the clique, and thus serves to increase the probability of it being able to be compacted with other compacted test plans.

The order of H1′, H2′, and H3′ can be interchanged.

FIG. 9 shows a second heuristic algorithm for obtaining an optimum compacted test plan according to the present invention. In step S1, after trying the compaction operation on arbitrary selected test plan pairs, one pair for which the partly compacted test plan length is the shortest is selected. In step S2, a partly compacted test plan is generated by scheduling the two test plans on appropriate time in the test plan scheduling table. In step S3, it is determined whether all the test plans have been scheduled in the test plan scheduling table. If all the test plans have been scheduled, the partly compacted test plan is taken as a compacted test plan, and the process is terminated. Otherwise, the process proceeds to step S4. In step S4, after trying the compaction operation on each pair consisting of the partly compacted test plan and a test plan not yet scheduled, one pair for which the partly compacted test plan length is the shortest is selected. In step S5, the partly compacted test plan is updated, while also updating scheduling results.

The operation of the algorithm of FIG. 9 will be described by using the GCD test plan examples shown in Table 1. When one pair of test plans that, when compacted, would yield the shortest test plan length is selected in S1 from among the test plans, as the test plan T6 for the circuit element 6 can be compacted with the test plan T5 for the circuit element 5 with a skew 0, and as the length after compaction is 2 which is the shortest (the pair of T5 and T6 is selected), then in S2, T5 and T6 are scheduled on time 0 in the test plan scheduling table as shown in Table 7, and the compaction operation ∩_{f} is performed to generate a partly compacted test plan (designated by PT1). In S3, as the test plans T4, T7, T11, T12, T13, and T14 are not yet scheduled, the process proceeds to S4.

TABLE 7

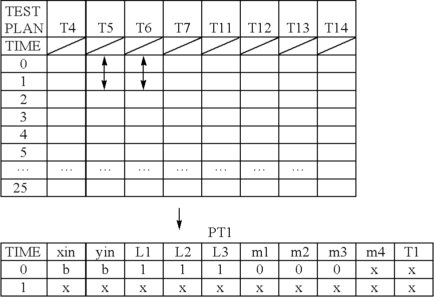

Then, in S4, as PT1 can be compacted with T11 with a skew 1, and as the length after compaction is 3 which is the shortest, T11 is selected. Next, in step S5, T11 is scheduled on time 0 and T5 and T6 on time 1 in the test plan scheduling table as shown in Table 8, and the compaction operation ∩_{f} is performed to generate a partly compacted test plan (designated by PT2). In S3, since the test plans T4, T7, T12, T13, and T14 are not yet scheduled, the process proceeds to S4.

TABLE 8

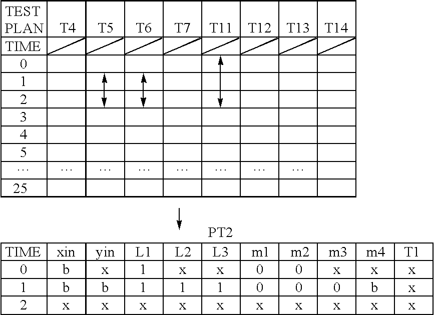

Then, in S4, as PT2 can be compacted with T4 with a skew 1, and as the length after compaction is 4 which is the shortest, T4 is selected. Next, in step S5, T4 is scheduled on time 0, T11 on time 1, and T5 and T6 on time 2 in the test plan scheduling table as shown in Table 9, and the compaction operation ∩_{f} is performed to generate a partly compacted test plan (designated by PT3). In S3, as the test plans T7, T12, T13, and T14 are not yet scheduled, the process proceeds to S4.

TABLE 9

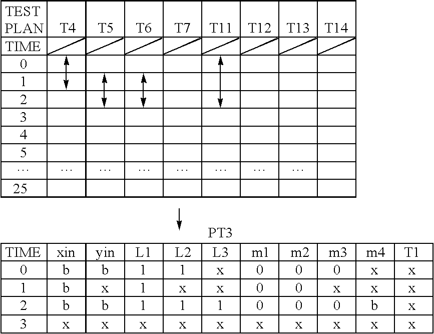

Then, in S4, as PT3 can be compacted with T12 with a skew 1, and as the length after compaction is 7 which is the shortest, T12 is selected. Next, in step S5, T12 is scheduled on time 0, T4 on time 3, T11 on time 4, and T5 and T6 on time 5 in the test plan scheduling table as shown in Table 10, and the compaction operation ∩_{f} is performed to generate a partly compacted test plan (designated by PT4). In S3, as the test plans T7, T13, and T14 are not yet scheduled, the process proceeds to S4.

TABLE 10

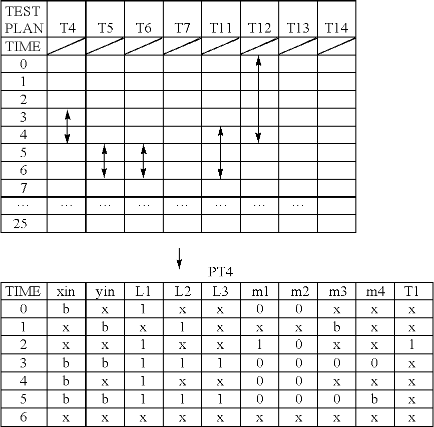

Then, in S4, as PT4 can be compact ed with T13 with a skew 0, and as the length after compaction is 7 which is the shortest, T13 is selected. Next, in step S5, T13 and T12 are scheduled on time 0, T4 on time 3, T11 on time 4, and T5 and T6 on time 5 in the test plan scheduling table as shown in Table 11, and the compaction operation ∩_{f} is performed to generate a partly compacted test plan (designated by PT5). In S3, since the test plans T7 and T14 are not yet scheduled, the process proceeds to S4.

TABLE 11

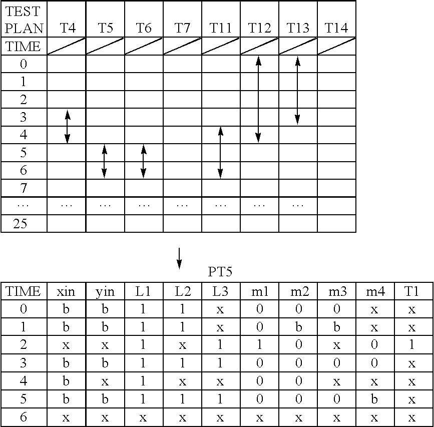

Then, in S4, as PT5 can be compacted with T14 with a skew 2, and as the length after compaction is 9 which is the shortest, T14 is selected. Next, in step S5, T14 is scheduled on time 0, T13 and T12 on time 2, T4 on time 5, T11 on time 6, and T5 and T6 on time 7 in the test plan scheduling table as shown in Table 12, and the compaction operation ∩_{f} is performed to generate a partly compacted test plan (designated by PT6). In S3, as the test plan T7 is not yet scheduled, the process proceeds to S4.

TABLE 12

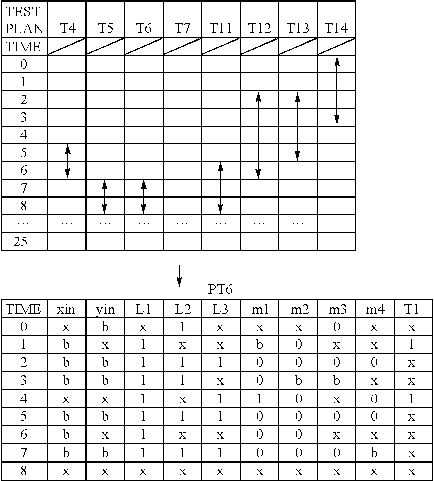

Then, in S4, as PT6 can be compacted with T7 with a skew 1, and as the length after compaction is 10 which is the shortest, T7 is selected. Next, in step S5, T7 is scheduled on time 0, T14 on time 1, T13 and T12 on time 3, T4 on time 6, T11 on time 7, and T5 and T6 on time 8 in the test plan scheduling table as shown in Table 13, and the compaction operation ∩_{f} is performed to generate a partly compacted test plan (designated by PT7). In S3, as the scheduling of all the test plans is completed, PT7 is determined as the compacted test plan table, and the process is terminated.

TABLE 13

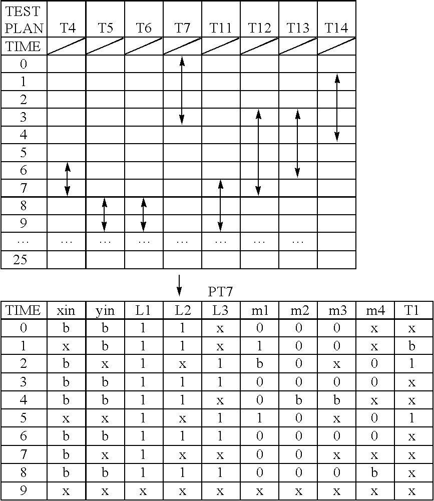

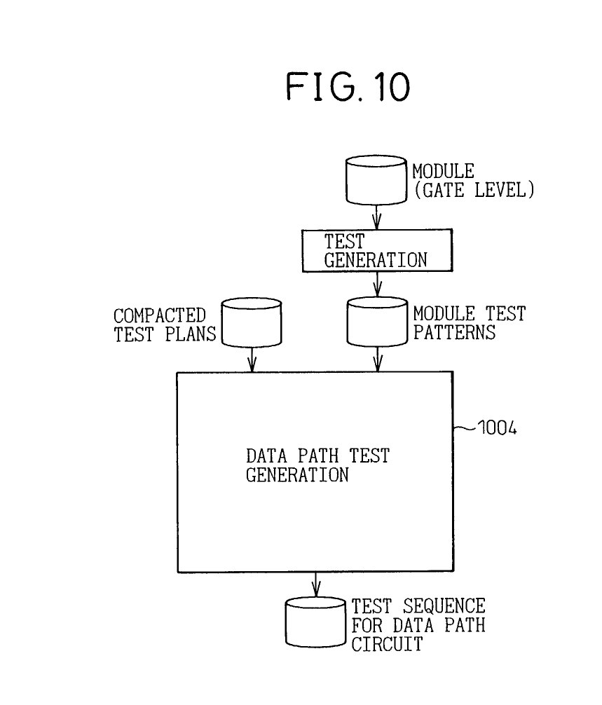

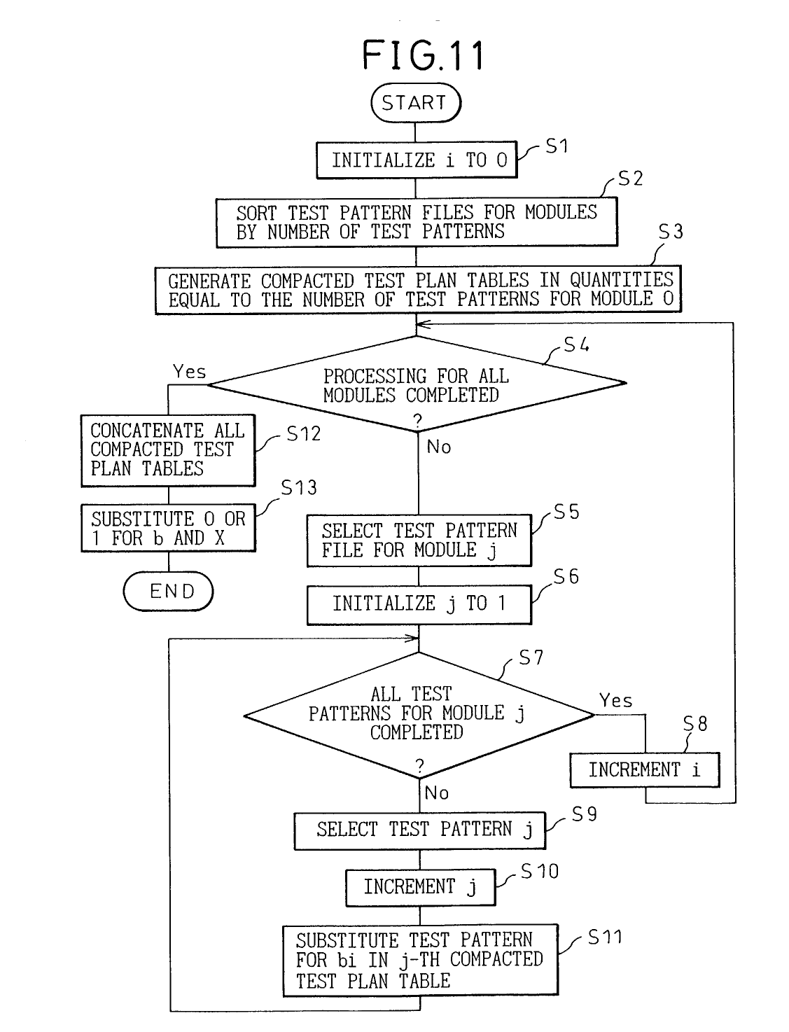

As shown in FIG. 10, in a test sequence generation process 1004 for generating a test sequence for a data path circuit using a compacted test plan, test pattern files each generated by performing test generation for each module (there are as many files as there are modules) and compacted test plans are input, and a test sequence for the data path circuit is output as the result. The test sequence generation flow for the data path circuit is shown in FIG. 11. In S1, the variable i indicating the number of modules is initialized to 0. In S2, the test pattern files for the respective modules are sorted in order of decreasing number of test patterns. In S3, as many compacted test plans as there are test patterns for the zeroth module are generated. in S4, it is determined whether the processing for all the modules has been completed, and if the processing has been completed, the process proceeds to S12; otherwise, the process proceeds to S5. In S5, the i-th module is selected. In S6, the variable j indicating the number of test patterns for the i-th module is initialized to 1. In S7, it is determined whether the processing for all the test patterns for the i-th module has been completed, and if the processing has been completed, the process proceeds to S8; otherwise, the process proceeds to S9. In S8, the variable i is incremented. In S9, the j-th test pattern for the i-th module is selected. In S10, the variable j is incremented. In S11, the j-th test pattern for the i-th module is substituted for b₁ in the j-th compacted test plan table. In S12, all the compacted test plan tables are concatenated to generate a test sequence for the data path. In S13, 0 or 1 is assigned randomly to any remaining b and X in the test sequence for the data path.

The compacted test plan shown in Table 14 is generated from the four test plans shown in Table 4 (in Table 14, b₁ indicates b in test plan T₁).

TABLE 14

| Time | P₀ | P₁ | P₂ | P₃ | P₄ |
|---|---|---|---|---|---|
| 0 | b₄ | 0 | 0 | 1 | X |
| 1 | X | b₃ | 0 | 1 | X |
| 2 | b₂ | 0 | 1 | X | X |
| 3 | X | b₁ | b₂ | X | 0 |
| 4 | b₁ | X | X | b₁ | X |
| 5 | X | X | X | 0 | X |

In this example, it is assumed that the test patterns for module 1 are V11 to V14 shown below.

V11=(P0, P1, P3)=(1, 0, 1)

V12=(P0, P1, P3)=(0, 0, 0)

V13=(PO, P1, P3)=(1, 1, 0)

V14=(P0, P1, P3)=(0, 1, 0)

It is assumed that the test patterns for module 2 are V21 to V24 shown below.

V21=(P0, P2)=(0, 0)

V22=(P0, P2)=(1, 0)

V23=(PO, P2)=(0, 1)

V24=(PO, P2)=(1, 1)

It is assumed that the test patterns for module 3 are V31 and V32 shown below.

V31=(P1)=(0)

V32=(P1)=(1)

It is assumed that the test patterns for module 4 are V41 and V42 shown below.

V41=(P0)=(1)

V42=(P0)=(1)

Test generation for the data path is performed by inserting the above test patterns into the compacted test plan of Table 14. First, four compacted test plans are generated, because the maximum number of test patterns for the modules is 4. Table 15 shows the results when the test patterns V11 to V42 are inserted in the four compacted test plans. The test sequence for the data path, created by concatenating the four compacted test plans, is shown in Table 16. Value 0 or 1 is entered randomly at the positions of the remaining b₁ and X in Table 16.

TABLE 15

| Time | P₀ | P₁ | P₂ | P₃ | P₄ |
|---|---|---|---|---|---|
| 0 | 0 | 0 | 0 | 1 | X |
| 1 | X | 0 | 0 | 1 | X |
| 2 | 0 | 0 | 1 | X | X |
| 3 | X | 0 | 0 | X | 0 |
| 4 | 1 | X | X | 1 | X |
| 5 | X | X | X | 0 | X |
| 0 | b₄ | 0 | 0 | 1 | X |
| 1 | X | b₃ | 0 | 1 | X |
| 2 | 0 | 0 | 1 | X | X |
| 3 | X | 1 | 1 | X | 0 |
| 4 | 1 | X | X | 0 | X |
| 5 | X | X | X | 0 | X |
| 0 | 1 | 0 | 0 | 1 | X |
| 1 | X | 1 | 0 | 1 | X |
| 2 | 1 | 0 | 1 | X | X |
| 3 | X | 0 | 0 | X | 0 |
| 4 | 0 | X | X | 0 | X |
| 5 | X | X | X | 0 | X |
| 0 | b₄ | 0 | 0 | 1 | X |
| 1 | X | b₃ | 0 | 1 | X |
| 2 | 1 | 0 | 1 | X | X |
| 3 | X | 1 | 1 | X | 0 |
| 4 | 0 | X | X | 0 | X |
| 5 | X | X | X | 0 | X |

TABLE 16

| Time | P₀ | P₁ | P₂ | P₃ | P₄ |
|---|---|---|---|---|---|
| 0 | 0 | 0 | 0 | 1 | X |
| 1 | X | 0 | 0 | 1 | X |
| 2 | 0 | 0 | 1 | X | X |
| 3 | X | 0 | 0 | X | 0 |
| 4 | 1 | X | X | 1 | X |
| 5 | X | X | X | 0 | X |
| 6 | 1 | 0 | 0 | 1 | X |
| 7 | X | 1 | 0 | 1 | X |
| 8 | 1 | 0 | 1 | X | X |
| 9 | X | 0 | 0 | X | 0 |
| 10 | 0 | X | X | 0 | X |
| 11 | X | X | X | 0 | X |
| 12 | b₄ | 0 | 0 | 1 | X |
| 13 | X | b₃ | 0 | 1 | X |
| 14 | 0 | 0 | 1 | X | X |
| 15 | X | 1 | 1 | X | 0 |
| 16 | 1 | X | X | 0 | X |
| 17 | X | X | X | 0 | X |
| 18 | b₄ | 0 | 0 | 1 | X |
| 19 | X | b₃ | 0 | 1 | X |
| 20 | 1 | 0 | 1 | X | X |
| 21 | X | 1 | 1 | X | 0 |
| 22 | 0 | X | X | 0 | X |
| 23 | X | X | X | 0 | X |

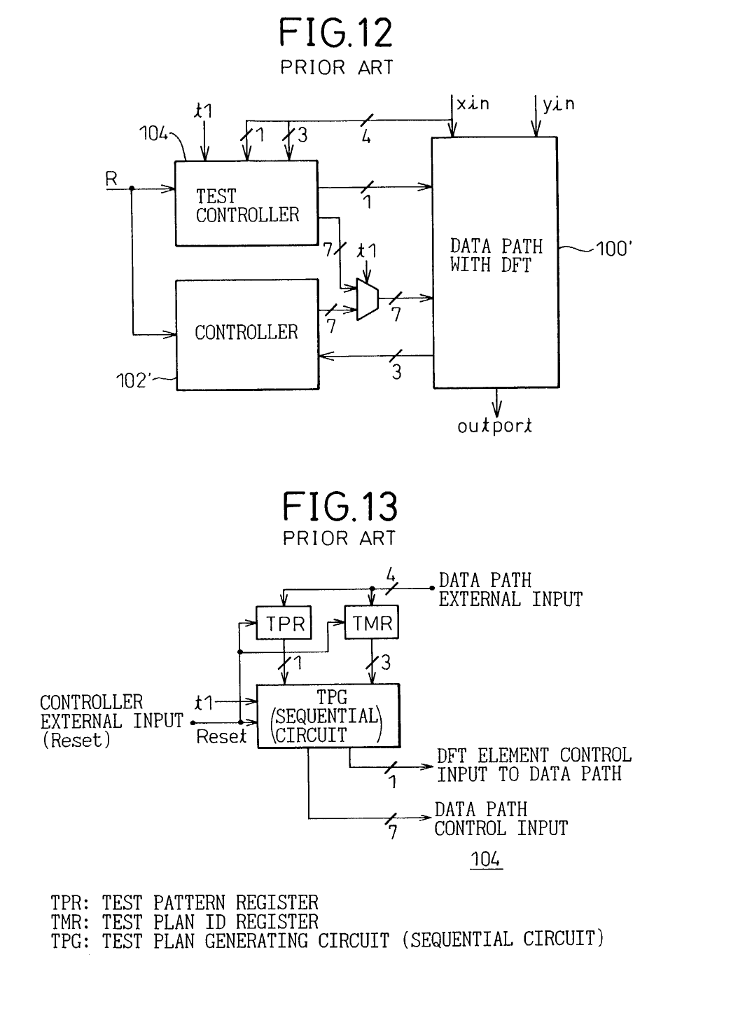

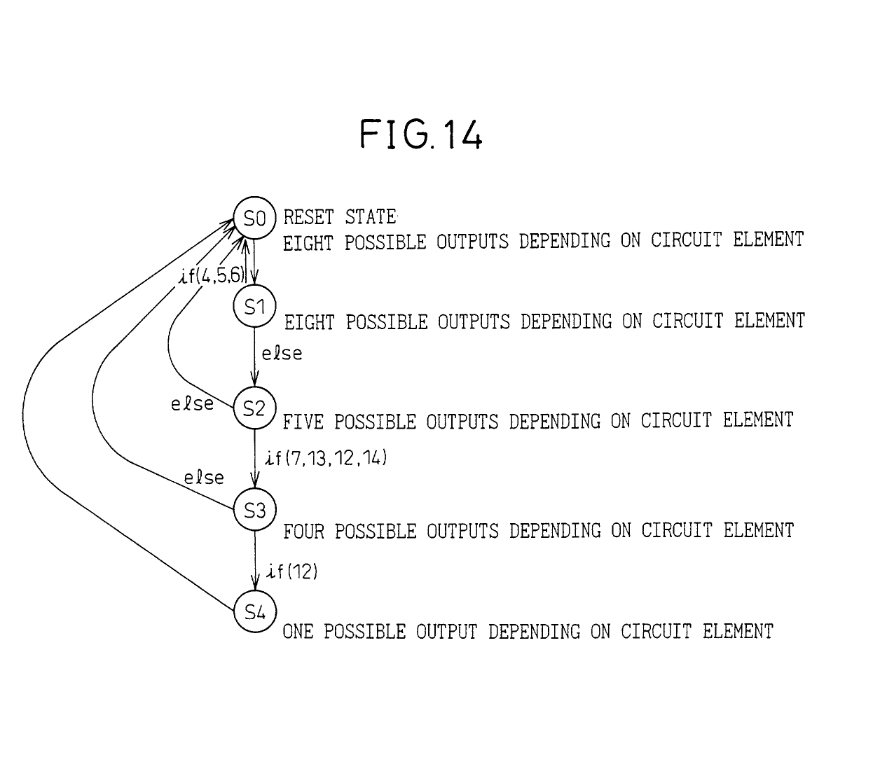

FIG. 12 is a diagram showing a GCD circuit having a test controller 104 that supplies a data path circuit with DFT 100′ with a test sequence generated in accordance with the prior art method by replacing b's in the GCD circuit test plans shown in Table 1 with test plans without compacting the test plans, and FIG. 13 is a diagram showing the details of the test controller 104. FIG. 14 is a state transition diagram for the test controller 104.

In FIG. 12, the test controller 104 takes as inputs a test mode signal t1, a controller reset signal, and four bits from an external input of the data path, and generates data path control signals (control signals to the existing modules and a control signal added for the purpose of DFT).

In FIG. 13, TMR is a test plan ID register for storing the IDs of the modules to be tested. In GCD, since there are eight modules to be tested, a log₂8=3-bit register is needed. TPR is a test pattern register which gives the value of b to the control signal for each module, the value of b being different for each target fault. In GCD, since no more than a one-bit control signal is needed for each module, only a 1 bit long register is needed. If there exists an external input whose value is always X at the time when b appears as control inputs in all the test plan, the value can be input into the control signal directly from that external input without passing through the TPR. TPR and TMR have load/hold functions, and are controlled by the reset input of the control circuit. When the reset is ON, the register is in load mode, and when it is OFF, the register is in hold mode.

In FIG. 14, since the number of states is equal to the maximum value of the test plan length for each module, five states are needed, and the bit width of the state register is therefore [log₂5]=3. (Here, [x] denotes x rounded down to the nearest integer. The same applies hereinafter.) Consider the case of testing the circuit element 11. For T11, b must be input at time 1 as the control input m4 (Table 1). Assume that the number of test patterns for testing T11 is four, of which there are two test patterns where the value of b is 0 and two test patterns where the value of b is 1. First, at time 0, R is set ON and t1 to 0 and, from xin, the ID (for example, 000) of the circuit element 11 is loaded into TMR and 0 into TPR. At time 1, R is set OFF and t to 1, and the value of T11 at time 0 is output as the control signal (S0). At time 2, the value of T11 at time 1 (the value of m4 is 0) is output as the control signal (S1). At time 3, the value of T11 at time 2 is output as the control signal (S2). At time 4, the value of T11 at time 0 is output as the control signal (S0). At time 5, the value of T11 at time 1 (the value of m4 is 0) is output as the control signal (S1). At time 6, the value of T11 at time 2 is output as the control signal (S2). At time 7, R is set ON and t1 to 0 and, from xin, the ID (000) of the circuit element 11 is loaded into TMR and 0 into TPR. At time 8, R is set OFF and t to 1, and the value of T11 at time 0 is output as the control signal (S0). At time 9, the value of T11 at time 1 (the value of m4 is 1) is output as the control signal (S1). At time 10, the value of T11 at time 2 is output as the control signal (S2). At time 11, the value of T11 at time 0 is output as the control signal (S0). At time 12, the value of T11 at time 1 (the value of m4 is 1) is output as the control signal (S1). At time 6, the value of T11 at time 2 is output as the control signal (S2). In this prior art test controller, the number of TMRs needed to identify all the modules is approximately equal to log₂n (n is the number of modules). Furthermore, in each state transition, a maximum of n conditional branches exist, and this requires an enormous amount of circuitry.

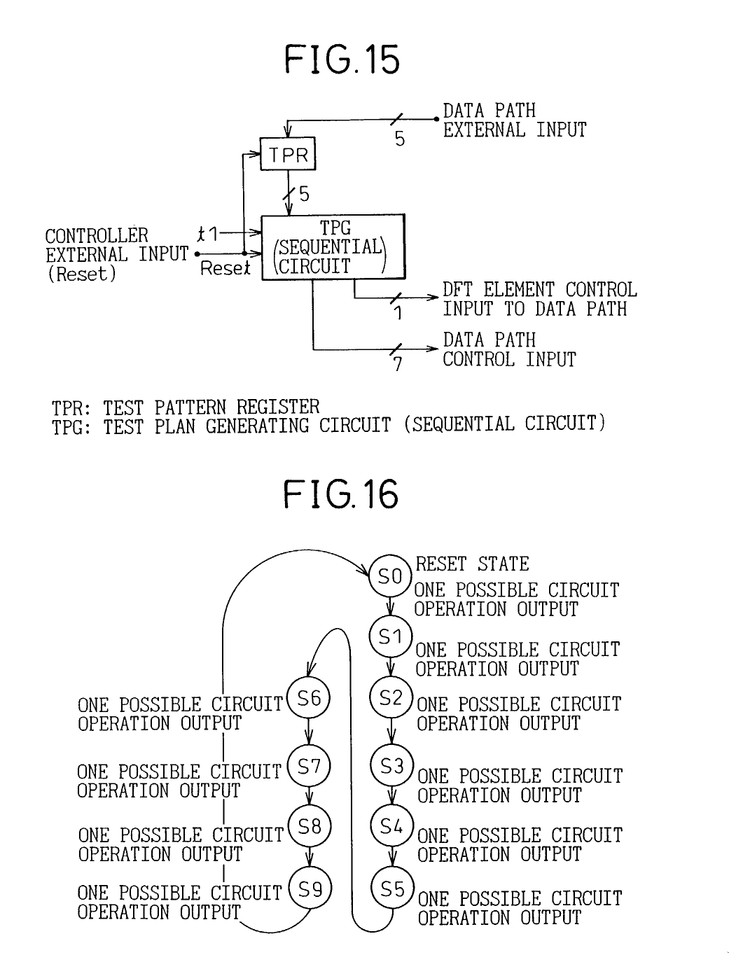

FIG. 15 shows a GCD test controller when the test generation method of the present invention using a compacted test plan is employed. As there are five b's as control inputs in the compacted test plan (see PT7 in Table 13), a 5-bit TPR is needed. Alternatively, if the TPR is not used, the two external inputs for testing can be input directly to the TPG, as there are a maximum of two b's as control inputs on the same time in the compacted test plan.

FIG. 16 is a state transition diagram for the test plan generating circuit of FIG. 15. In FIG. 16, the length of the GCD compacted test plan is 10, and the number of states is therefore 10. With [log₂10], the bit width of the state register is 4. When t1=1, a state transition occurs, and no if statement is needed for output, but only a set of control inputs is output. Since no if statement is needed for output, in the case of a large scale circuit having a large number of modules the area of the TPG combinational circuit can be drastically reduced compared with the prior art method.

In the test sequence of Table 16, there are a number of bi's left unfilled with actual test pattern values. This occurs because the number of test patterns is not equal for all the modules (circuit elements). Therefore, if the plurality of test plans are classified into a plurality of groups according to an estimated number of test patterns for each module, and if a compacted test plan is generated for each group, test patterns are inserted, and the compacted test plans thus generated are concatenated, then the entire length of the test sequence can be shortened.

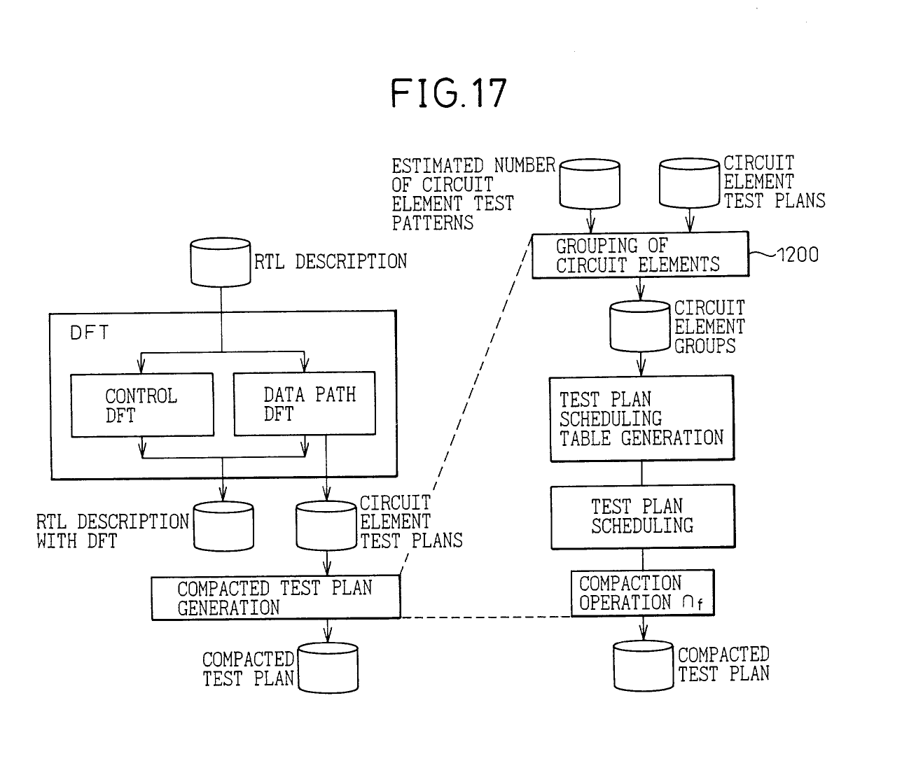

FIG. 17 shows a processing flow for generating a plurality of compacted test plans by grouping test plans. In addition to the flow of FIG. 6, an estimated number of test patterns for each circuit element is input, and the test plans are grouped according to the number of test patterns (step 1200); then, a compacted test plan is generated for each group.

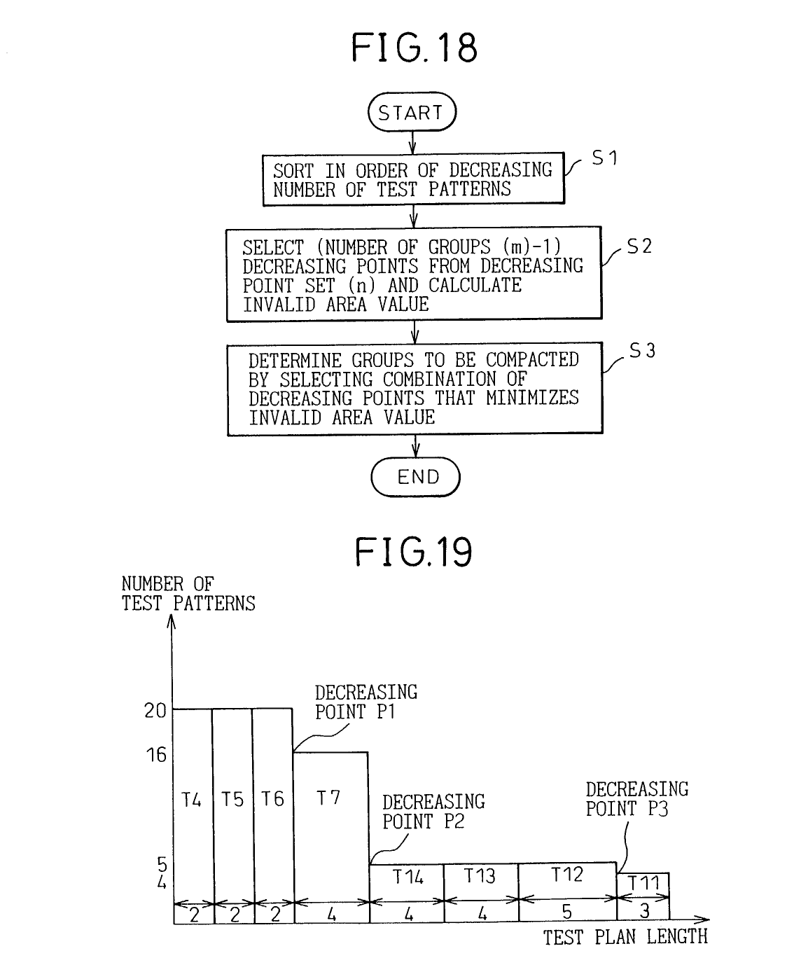

FIG. 18 shows the processing flow for test plan grouping. In S1, the test plans are sorted in order of decreasing number of test patterns for the circuit modules. In S2, the point at which the number of test patterns changes between test plans when the test plans are sorted is defined as a decreasing point, and an invalid area value is calculated for all possible combinations of decreasing points the number of which is equal to the specified number of groups minus 1. The invalid area value is defined by

$${{\sum }^{n}}_{i = 1} ( ( max\_N - {N}_{1} ) \times {L}_{i} )$$

where n is the number of test plans, max_N is the maximum number of test patterns within the group to which each module belongs, Nᵢ is the number of test patterns for module i, and Lᵢ is the test plan length for module i. The invalid area value indicates the test sequence length that is rendered invalid. In S3, the combination of decreasing points that minimizes the invalid area value is selected, and the test plans are grouped for the generation of a compacted test plan.

FIG. 19 shows an example of GCD test plan grouping. As shown, the number of test patterns is 20 for each of T4, T5, and T6, 16 for T7, 5 for T14, T13, and T12, and 4 for T11. In S1, the test plans are sorted as shown in FIG. 19. Three decreasing points P1, P2, and P3 are formed as shown. Here, if the test plans are to be divided into three groups, two decreasing points must be selected. With ₃C₂, there are three possible combinations of decreasing points. In S2, the invalid area value is calculated for each of the three combinations. When the decreasing points P1 and P2 are selected, the invalid area value is 3; when the decreasing points P1 and P3 are selected, the invalid area value is 143; and when the decreasing points P2 and P3 are selected, the invalid area value is 16. In S3, the combination of the decreasing points P1 and P2 for which the invalid area value is the smallest, i.e., 3, is selected. T4, T5, and T6 are grouped together (G1), T7 forms a group by itself (G2), and T14, T13, T12, and T11 are grouped together (G3). The compacted test plans generated for the respective groups are shown in Table 17. The test sequence length for the entire data path is 159.

TABLE 17
COMPACTED TEST PLANS GENERATED
BY GROUPING BASED ON
P1 AND P2

| | | | | | | | | | | |
|---|---|---|---|---|---|---|---|---|---|---|
| TIME | xin | yin | L1 | L2 | L3 | m1 | m2 | m3 | m4 | T1 |

(a) G1 (T4, T5, T6)

| | | | | | | | | | | |
|---|---|---|---|---|---|---|---|---|---|---|
| 0 | b | b | 1 | 1 | X | 0 | 0 | 0 | X | X |
| 1 | b | b | 1 | 1 | X | 0 | 0 | 0 | X | X |
| 2 | X | X | X | X | X | X | X | X | X | X |

(b) G2 (T7)

| | | | | | | | | | | |
|---|---|---|---|---|---|---|---|---|---|---|
| 0 | b | b | 1 | 1 | X | 0 | 0 | 0 | X | X |
| 1 | X | X | 1 | X | X | 1 | 0 | X | X | b |
| 2 | X | X | X | X | 1 | X | X | X | 0 | X |
| 3 | X | X | X | X | X | X | X | X | X | X |

(c) G3 (T11, T12, T13, T14)

| | | | | | | | | | | |
|---|---|---|---|---|---|---|---|---|---|---|
| 0 | b | X | 1 | X | X | 0 | 0 | X | X | X |
| 1 | b | b | 1 | 1 | X | 0 | 0 | b | X | X |
| 2 | X | b | 1 | 1 | 1 | 1 | 0 | 0 | b | 1 |
| 3 | b | b | 1 | 1 | 1 | 0 | b | 0 | 0 | X |
| 4 | b | X | 1 | X | 1 | b | 0 | X | 0 | 1 |
| 5 | X | X | X | X | 1 | X | X | X | 0 | X |
| 6 | X | X | X | X | X | X | X | X | X | X |

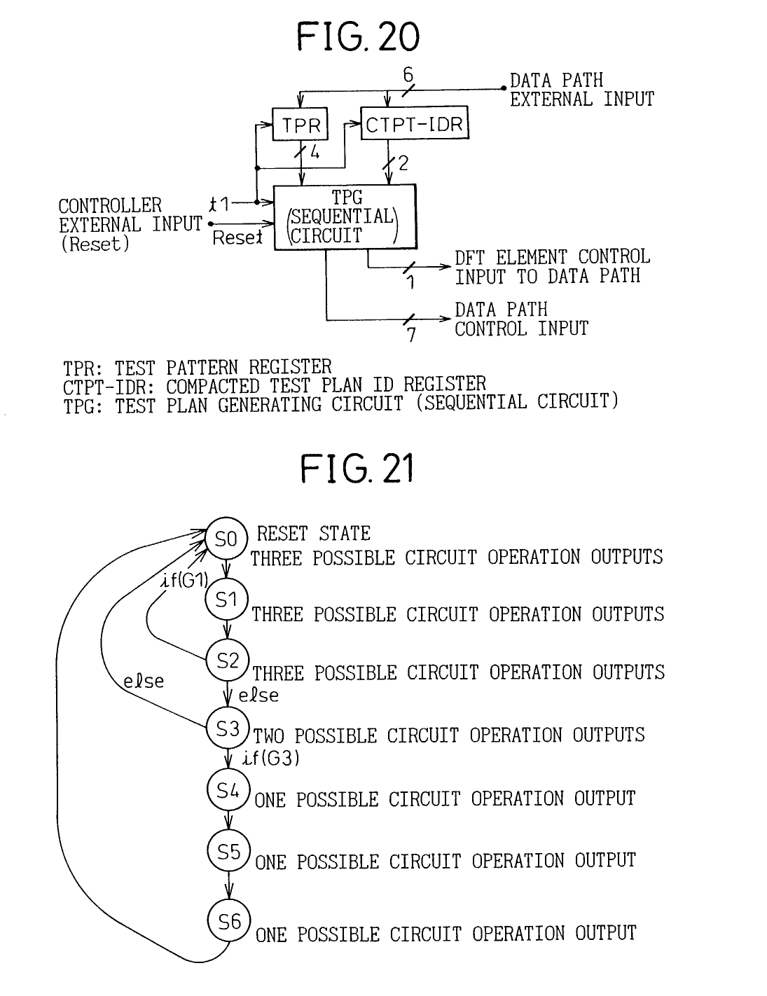

FIG. 20 is a diagram showing a GCD test controller for the case where the three compacted test plans (Table 17) are used. The number of b's as control inputs in Table 17(c) is 4 which is the largest in Table 17, so that the bit width of TPR is four bits. Further, to identify the three compacted test plans, the bit width of CTPT-IDR is [log₂3]=2 bits.

FIG. 21 shows a state transition diagram for the GCD test controller when the three compacted test plan tables are used. The length of the compacted test plan of Table 17(c) is 7 which is the longest; therefore, the number of states is 7 and the bit width of the state register is [log₂7]=3 bits. In each state, there are a maximum of three kinds of control inputs.

As is apparent from the example of FIG. 19, the number of test patterns is relatively small for selectors or multiplexers (in the example of FIG. 19, the circuit elements 11 to 14 in FIG. 3). Further, if the test results of the other circuit elements show that they are operating normally, then in most cases the above-mentioned circuit elements should also be operating normally. In view of this, if the compacted test plans are generated by excluding the test plans for the selectors or multiplexers, the test sequence length can be further shortened. In the example of the above GCD circuit, the compacted test plan shown in Table 18 is obtained by generating compacted test plans from the test plans T4 to T7, and the resulting test sequence length is 100.

TABLE 18

| | | | | | | | | | | |
|---|---|---|---|---|---|---|---|---|---|---|
| TIME | xin | yin | L1 | L2 | L3 | m1 | m2 | m3 | m4 | T1 |

T4, T5, T6, T7

| | | | | | | | | | | |
|---|---|---|---|---|---|---|---|---|---|---|
| 0 | b | b | 1 | 1 | X | 0 | 0 | 0 | X | X |
| 1 | X | X | 1 | X | X | 1 | 0 | X | X | b |
| 2 | b | b | 1 | 1 | 1 | 0 | 0 | 0 | 0 | X |
| 3 | b | b | 1 | 1 | X | 0 | 0 | 0 | X | X |
| 4 | X | X | X | X | X | X | X | X | X | X |

When generating the compacted test plan, if the number of test patterns necessary for each circuit element is known, test plans (each called a test) are created in quantities equal to the number of test patterns, and are compacted (hereinafter called the compacted test); then, a test sequence can be generated by inserting test patterns in the compacted test. For example, when the test plans T1 to T3 for the circuit elements 1 to 3 are given as shown in Tables 19 to 21, and the number of test patterns is 1, 2, and 1, respectively, for the circuit elements 1 to 3, then the tests T₁₁, T₂₁, T₂₂, and T₃₁ are generated and are scheduled as shown in Table 22, and the compacted test shown in Table 23 is generated.

TABLE 19
T₁

| Time | P₀ | P₁ | P₂ | P₃ |
|---|---|---|---|---|
| 0 | b | X | X | 0 |
| 1 | X | b | X | 1 |
| 2 | X | X | 0 | X |
| 3 | X | 0 | X | b |

TABLE 20
T₂

| Time | P₀ | P₁ | P₂ | P₃ |
|---|---|---|---|---|
| 0 | b | X | X | 0 |
| 1 | X | X | X | X |
| 2 | X | b | 1 | X |
| 3 | X | X | X | X |

TABLE 21
T₃

| Time | P₀ | P₁ | P₂ | P₃ |
|---|---|---|---|---|
| 0 | b | b | X | X |
| 1 | X | X | 1 | 0 |
| 2 | b | X | 0 | 1 |
| 3 | X | b | X | b |
| 4 | X | X | 0 | X |
| 5 | X | X | X | X |

TABLE 22

| Test | T₁₁ | | | | T₂₁ | | | | T₂₂ | | | | T₃₁ | | | |
|---|---|---|---|---|---|---|---|---|---|---|---|---|---|---|---|---|
| Time | P₀ | P₁ | P₂ | P₃ | P₀ | P₁ | P₂ | P₃ | P₀ | P₁ | P₂ | P₃ | P₀ | P₁ | P₂ | P₃ |
| 0 | | | | | b | X | X | 0 | | | | | | | | |
| 1 | | | | | X | X | X | X | | | | | b | b | X | X |
| 2 | b | X | X | 0 | X | b | 1 | X | | | | | X | X | 1 | 0 |
| 3 | X | b | X | 1 | X | X | X | X | | | | | b | X | 0 | 1 |
| 4 | X | X | 0 | X | | | | | | | | | X | b | X | b |
| 5 | X | 0 | X | b | | | | | | | | | X | X | 0 | X |
| 6 | | | | | | | | | b | X | X | 0 | X | X | X | X |
| 7 | | | | | | | | | X | X | X | X | | | | |
| 8 | | | | | | | | | X | b | 1 | X | | | | |
| 9 | | | | | | | | | X | X | X | X | | | | |
| 10 | | | | | | | | | | | | | | | | |
| 11 | | | | | | | | | | | | | | | | |
| 12 | | | | | | | | | | | | | | | | |
| 13 | | | | | | | | | | | | | | | | |
| 14 | | | | | | | | | | | | | | | | |
| 15 | | | | | | | | | | | | | | | | |
| 16 | | | | | | | | | | | | | | | | |
| 17 | | | | | | | | | | | | | | | | |

TABLE 23

| Time | P₀ | P₁ | P₂ | P₃ |
|---|---|---|---|---|
| 0 | b | X | X | 0 |
| 1 | b | b | X | X |
| 2 | b | b | 1 | 0 |
| 3 | b | b | 0 | 1 |
| 4 | X | b | 0 | b |
| 5 | X | 0 | 0 | 1 |
| 6 | b | X | X | 0 |
| 7 | X | X | X | X |
| 8 | X | b | 1 | X |
| 9 | X | X | X | X |

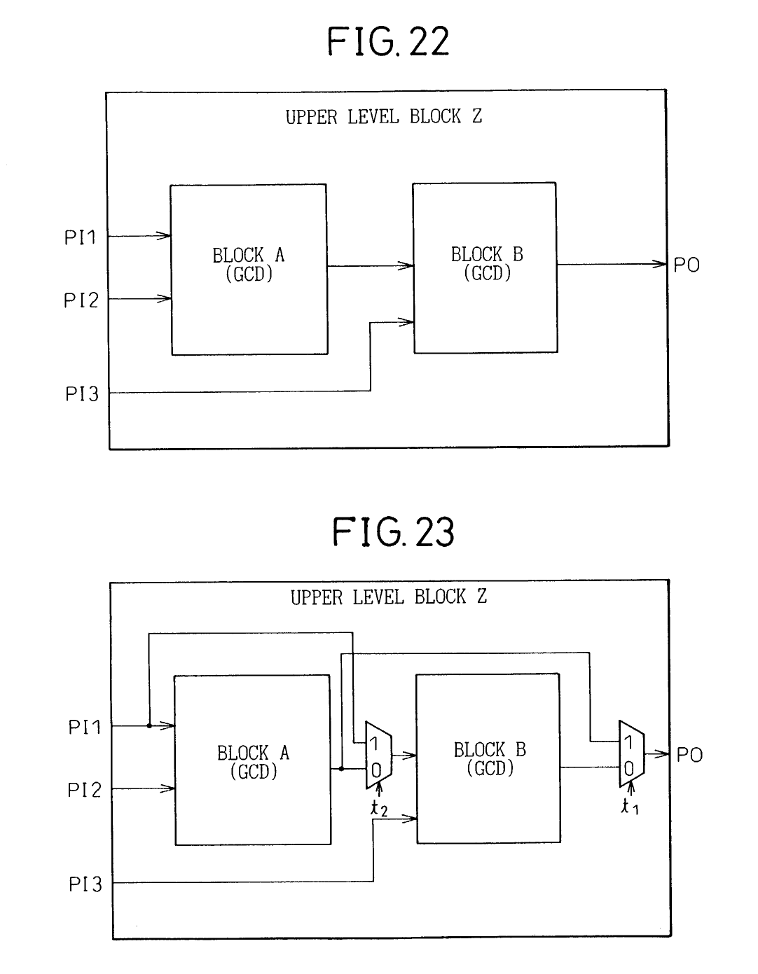

FIG. 22 shows a hierarchically structured circuit in which an upper level block Z includes two GCD circuit blocks A and B. If each of the blocks A and B is strongly testable from outside the block, then by adding two selectors as shown in FIG. 23, the blocks are also strongly testable from outside the upper level block, and their pin assignment tables are as shown in Table 24.

TABLE 24
(a) PIN ASSIGNMENT TABLE FOR BLOCK A

| | | | |
|---|---|---|---|
| BLOCK PIN | Xin | Yin | Outport |
| UPPER LEVEL | PI1 | PI2 | PO |
| PIN | | | |
| CONDITION | NONE | NONE | t1 = 1 |

(b) PIN ASSIGNMENT TABLE FOR BLOCK B

| | | | |
|---|---|---|---|
| BLOCK PIN | Xin | Yin | Outport |
| UPPER LEVEL | PI1 | PI3 | PO |
| PIN | | | |
| CONDITION | t2 = 1 | NONE | t1 = 0 |

When the test plans in Table 1 are converted in accordance with the above pin assignment tables into test plans to be applied from the pins of the upper module Z, test plans such as shown in Tables 25 and 26 are obtained for the respective circuit blocks A and B.

TABLE 25

| | | | | | | | | | | | | | | | | | | | | | |
|---|---|---|---|---|---|---|---|---|---|---|---|---|---|---|---|---|---|---|---|---|---|
| TIME | P11 | P12 | P13 | L1 | L2 | L3 | m1 | m2 | m3 | m4 | T1 | L1′ | L2′ | L3′ | m1′ | m2′ | m3′ | m4′ | T1′ | t1 | t2 |

CIRCUIT ELEMENT 11 IN BLOCK A

| | | | | | | | | | | | | | | | | | | | | | |
|---|---|---|---|---|---|---|---|---|---|---|---|---|---|---|---|---|---|---|---|---|---|
| 0 | b | x | x | 1 | x | x | 0 | 0 | x | x | x | x | x | x | x | x | x | x | x | x | x |
| 1 | x | x | x | x | x | 1 | x | x | x | b | x | x | x | x | x | x | x | x | x | x | x |
| 2 | x | x | x | x | x | x | x | x | x | x | x | x | x | x | x | x | x | x | x | 1 | x |

CIRCUIT ELEMENT 12 IN BLOCK A

| | | | | | | | | | | | | | | | | | | | | | |
|---|---|---|---|---|---|---|---|---|---|---|---|---|---|---|---|---|---|---|---|---|---|
| 0 | b | x | x | 1 | x | x | 0 | 0 | x | x | x | x | x | x | x | x | x | x | x | x | x |
| 1 | x | b | x | x | 1 | x | x | x | b | x | x | x | x | x | x | x | x | x | x | x | x |
| 2 | x | x | x | 1 | x | x | 1 | 0 | x | x | 1 | x | x | x | x | x | x | x | x | x | x |
| 3 | x | x | x | x | x | 1 | x | x | x | 0 | x | x | x | x | x | x | x | x | x | x | x |
| 4 | x | x | x | x | x | x | x | x | x | x | x | x | x | x | x | x | x | x | x | 1 | x |

CIRCUIT ELEMENT 13 IN BLOCK A

| | | | | | | | | | | | | | | | | | | | | | |
|---|---|---|---|---|---|---|---|---|---|---|---|---|---|---|---|---|---|---|---|---|---|
| 0 | x | b | x | x | 1 | x | x | x | 0 | x | x | x | x | x | x | x | x | x | x | x | x |
| 1 | b | x | x | 1 | x | x | 0 | b | x | x | x | x | x | x | x | x | x | x | x | x | x |
| 2 | x | x | x | x | x | 1 | x | x | x | 0 | x | x | x | x | x | x | x | x | x | x | x |
| 3 | x | x | x | x | x | x | x | x | x | x | x | x | x | x | x | x | x | x | x | 1 | x |

CIRCUIT ELEMENT 14 IN BLOCK A

| | | | | | | | | | | | | | | | | | | | | | |
|---|---|---|---|---|---|---|---|---|---|---|---|---|---|---|---|---|---|---|---|---|---|
| 0 | x | b | x | x | 1 | x | x | x | 0 | x | x | x | x | x | x | x | x | x | x | x | x |
| 1 | b | x | x | 1 | x | x | b | 0 | x | x | 1 | x | x | x | x | x | x | x | x | x | x |
| 2 | x | x | x | x | x | 1 | x | x | x | 0 | x | x | x | x | x | x | x | x | x | x | x |
| 3 | x | x | x | x | x | x | x | x | x | x | x | x | x | x | x | x | x | x | x | 1 | x |

CIRCUIT ELEMENT 7 IN BLOCK A

| | | | | | | | | | | | | | | | | | | | | | |
|---|---|---|---|---|---|---|---|---|---|---|---|---|---|---|---|---|---|---|---|---|---|
| 0 | b | b | x | 1 | 1 | x | 0 | 0 | 0 | x | x | x | x | x | x | x | x | x | x | x | x |
| 1 | x | x | x | 1 | x | x | 1 | 0 | x | x | b | x | x | x | x | x | x | x | x | x | x |
| 2 | x | x | x | x | x | 1 | x | x | x | 0 | x | x | x | x | x | x | x | x | x | x | x |
| 3 | x | x | x | x | x | x | x | x | x | x | x | x | x | x | x | x | x | x | x | 1 | x |

CIRCUIT ELEMENT 6 IN BLOCK A

| | | | | | | | | | | | | | | | | | | | | | |
|---|---|---|---|---|---|---|---|---|---|---|---|---|---|---|---|---|---|---|---|---|---|
| 0 | b | x | x | 1 | x | x | 0 | 0 | x | x | x | x | x | x | x | x | x | x | x | x | x |
| 1 | x | x | x | x | x | x | x | x | x | x | x | x | x | x | x | x | x | x | x | 1 | x |

CIRCUIT ELEMENT 5 IN BLOCK A

| | | | | | | | | | | | | | | | | | | | | | |
|---|---|---|---|---|---|---|---|---|---|---|---|---|---|---|---|---|---|---|---|---|---|
| 0 | x | b | x | x | 1 | x | x | x | 0 | x | x | x | x | x | x | x | x | x | x | x | x |
| 1 | x | x | x | x | x | x | x | x | x | x | x | x | x | x | x | x | x | x | x | 1 | x |

CIRCUIT ELEMENT 4 IN BLOCK A

| | | | | | | | | | | | | | | | | | | | | | |
|---|---|---|---|---|---|---|---|---|---|---|---|---|---|---|---|---|---|---|---|---|---|
| 0 | b | b | x | 1 | 1 | x | 0 | 0 | 0 | x | x | x | x | x | x | x | x | x | x | x | x |
| 1 | x | x | x | x | x | x | x | x | x | x | x | x | x | x | x | x | x | x | x | 1 | x |

TABLE 26

| | | | | | | | | | | | | | | | | | | | | | |
|---|---|---|---|---|---|---|---|---|---|---|---|---|---|---|---|---|---|---|---|---|---|
| TIME | P11 | P12 | P13 | L1 | L2 | L3 | m1 | m2 | m3 | m4 | T1 | L1′ | L2′ | L3′ | m1′ | m2′ | m3′ | m4′ | T1′ | t1 | t2 |

CIRCUIT ELEMENT 11 IN BLOCK B

| | | | | | | | | | | | | | | | | | | | | | |
|---|---|---|---|---|---|---|---|---|---|---|---|---|---|---|---|---|---|---|---|---|---|
| 0 | b | x | x | x | x | x | x | x | x | x | x | 1 | x | x | 0 | 0 | x | x | x | x | 1 |
| 1 | x | x | x | x | x | x | x | x | x | x | x | x | x | 1 | x | x | x | b | x | x | x |
| 2 | x | x | x | x | x | x | x | x | x | x | x | x | x | x | x | x | x | x | x | 0 | x |

CIRCUIT ELEMENT 12 IN BLOCK B

| | | | | | | | | | | | | | | | | | | | | | |
|---|---|---|---|---|---|---|---|---|---|---|---|---|---|---|---|---|---|---|---|---|---|
| 0 | b | x | x | x | x | x | x | x | x | x | x | 1 | x | x | 0 | 0 | x | x | x | x | 1 |
| 1 | x | x | b | x | x | x | x | x | x | x | x | x | 1 | x | x | x | b | x | x | x | x |
| 2 | x | x | x | x | x | x | x | x | x | x | x | 1 | x | x | 1 | 0 | x | x | 1 | x | x |
| 3 | x | x | x | x | x | x | x | x | x | x | x | x | x | 1 | x | x | x | 0 | x | x | x |
| 4 | x | x | x | x | x | x | x | x | x | x | x | x | x | x | x | x | x | x | x | 0 | x |

CIRCUIT ELEMENT 13 IN BLOCK B

| | | | | | | | | | | | | | | | | | | | | | |
|---|---|---|---|---|---|---|---|---|---|---|---|---|---|---|---|---|---|---|---|---|---|
| 0 | x | x | b | x | x | x | x | x | x | x | x | x | 1 | x | x | x | 0 | x | x | x | x |
| 1 | b | x | x | x | x | x | x | x | x | x | x | 1 | x | x | 0 | b | x | x | x | x | 1 |
| 2 | x | x | x | x | x | x | x | x | x | x | x | x | x | 1 | x | x | x | 0 | x | x | x |
| 3 | x | x | x | x | x | x | x | x | x | x | x | x | x | x | x | x | x | x | x | 0 | x |

CIRCUIT ELEMENT 14 IN BLOCK B

| | | | | | | | | | | | | | | | | | | | | | |
|---|---|---|---|---|---|---|---|---|---|---|---|---|---|---|---|---|---|---|---|---|---|
| 0 | x | x | b | x | x | x | x | x | x | x | x | x | 1 | x | x | x | 0 | x | x | x | x |
| 1 | b | x | x | x | x | x | x | x | x | x | x | 1 | x | x | b | 0 | x | x | 1 | x | 1 |
| 2 | x | x | x | x | x | x | x | x | x | x | x | x | x | 1 | x | x | x | 0 | x | x | x |
| 3 | x | x | x | x | x | x | x | x | x | x | x | x | x | x | x | x | x | x | x | 0 | x |

CIRCUIT ELEMENT 7 IN BLOCK B

| | | | | | | | | | | | | | | | | | | | | | |
|---|---|---|---|---|---|---|---|---|---|---|---|---|---|---|---|---|---|---|---|---|---|
| 0 | b | x | b | x | x | x | x | x | x | x | x | 1 | 1 | x | 0 | 0 | 0 | x | x | x | 1 |
| 1 | x | x | x | x | x | x | x | x | x | x | x | 1 | x | x | 1 | 0 | x | x | b | x | x |
| 2 | x | x | x | x | x | x | x | x | x | x | x | x | x | 1 | x | x | x | 0 | x | x | x |
| 3 | x | x | x | x | x | x | x | x | x | x | x | x | x | x | x | x | x | x | x | 0 | x |

CIRCUIT ELEMENT 6 IN BLOCK B

| | | | | | | | | | | | | | | | | | | | | | |
|---|---|---|---|---|---|---|---|---|---|---|---|---|---|---|---|---|---|---|---|---|---|
| 0 | b | x | x | x | x | x | x | x | x | x | x | 1 | x | x | 0 | 0 | x | x | x | x | 1 |
| 1 | x | x | x | x | x | x | x | x | x | x | x | x | x | x | x | x | x | x | x | 0 | x |

CIRCUIT ELEMENT 5 IN BLOCK B

| | | | | | | | | | | | | | | | | | | | | | |
|---|---|---|---|---|---|---|---|---|---|---|---|---|---|---|---|---|---|---|---|---|---|
| 0 | x | x | b | x | x | x | x | x | x | x | x | x | 1 | x | x | x | 0 | x | x | x | x |
| 1 | x | x | x | x | x | x | x | x | x | x | x | x | x | x | x | x | x | x | x | 0 | x |

CIRCUIT ELEMENT 4 IN BLOCK B

| | | | | | | | | | | | | | | | | | | | | | |
|---|---|---|---|---|---|---|---|---|---|---|---|---|---|---|---|---|---|---|---|---|---|
| 0 | b | x | b | x | x | x | x | x | x | x | x | 1 | 1 | x | 0 | 0 | 0 | x | x | x | 1 |
| 1 | x | x | x | x | x | x | x | x | x | x | x | x | x | x | x | x | x | x | x | 0 | x |

These 16 test plans are scheduled in a test plan scheduling table, and based on the results, the compaction operation is performed to generate the compacted test plan shown in Table 27. As the length of the compacted test plan is 15, and the maximum number of test patterns is 20 (see FIG. 19), the test sequence length for the data paths in the blocks A and B is 300. On the other hand, in the case of testing the blocks A and B in sequence using the compacted test plans individually generated for the respective blocks A and B, as the length of each compacted test plan is 10, the entire test sequence length can be greatly reduced if the blocks A and B are tested in parallel.

TABLE 27

| TIME | R1 | R2 | R3 | L1 | L2 | L3 | m1 | m2 | m3 | m4 | T1 | L1 | L2 | L3 | m1 | m2 | m3 | m4 | T1 | t1 | t2 |
|---|---|---|---|---|---|---|---|---|---|---|---|---|---|---|---|---|---|---|---|---|---|
| 0 | b | x | x | 1 | x | x | 0 | 0 | x | x | x | x | x | x | x | x | x | x | x | x | x |
| 1 | b | b | x | x | 1 | x | x | x | b | x | x | 1 | x | x | 0 | 0 | x | x | x | x | 1 |
| 2 | b | x | b | 1 | x | x | 1 | 0 | x | x | 1 | 1 | 1 | 1 | 0 | 0 | 0 | b | x | x | 1 |
| 3 | b | b | b | 1 | 1 | 1 | 0 | 0 | 0 | 0 | x | x | 1 | x | x | x | 0 | x | x | 0 | x |
| 4 | b | b | x | x | 1 | 1 | x | x | 0 | b | x | 1 | x | x | 0 | b | x | x | x | 1 | 1 |
| 5 | b | b | x | 1 | 1 | x | 0 | b | 0 | x | x | x | x | 1 | x | x | x | 0 | x | 1 | x |
| 6 | b | x | b | 1 | x | 1 | b | 0 | x | 0 | 1 | x | 1 | x | x | x | 0 | x | x | 0 | x |
| 7 | b | x | x | x | x | 1 | x | x | x | 0 | x | 1 | x | x | b | 0 | x | x | 1 | 1 | 1 |
| 8 | b | x | x | x | x | x | x | x | x | x | x | 1 | x | 1 | 0 | 0 | x | 0 | x | 1 | 1 |
| 9 | b | b | b | 1 | 1 | x | 0 | 0 | 0 | x | x | x | 1 | x | x | x | b | x | x | 0 | x |
| 10 | b | b | x | 1 | 1 | x | 0 | 0 | 0 | x | x | 1 | x | x | 1 | 0 | x | x | 1 | 1 | x |
| 11 | b | x | b | 1 | x | x | 1 | 0 | x | x | b | 1 | 1 | 1 | 0 | 0 | 0 | 0 | x | x | 1 |
| 12 | b | x | x | 1 | x | 1 | 0 | 0 | x | 0 | x | 1 | x | x | 1 | 0 | x | x | b | 0 | x |
| 13 | b | x | b | x | x | x | x | x | x | x | x | 1 | 1 | 1 | 0 | 0 | 0 | 0 | x | 1 | 1 |
| 14 | x | x | x | x | x | x | x | x | x | x | x | x | x | x | x | x | x | x | x | 0 | x |

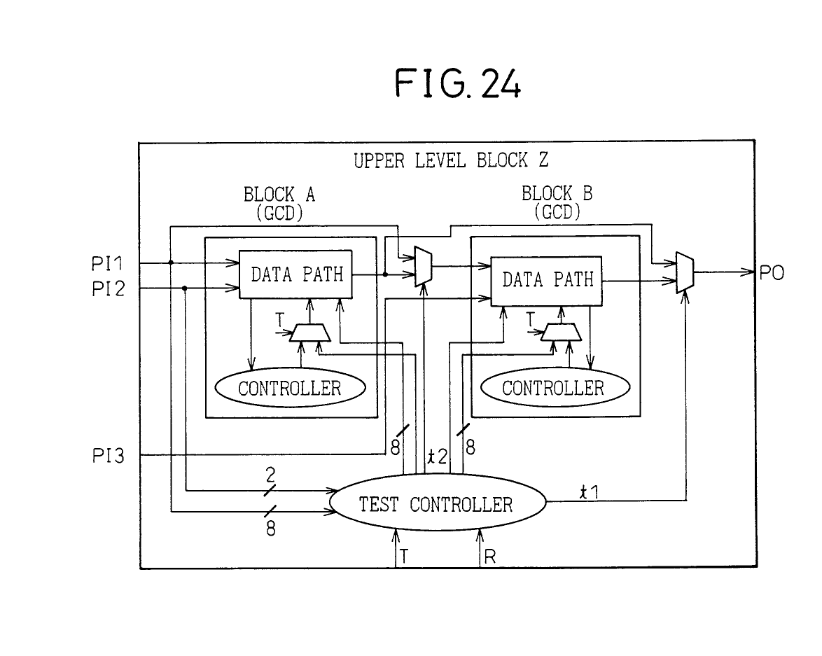

FIG. 24 is a diagram showing the intire circuit in which the test controller is inserted. The test controller drives the control inputs to the data path in each block. From Table 27, it is seen that a 10-bit TPR is needed, and the number of states is 15; therefore, the state register is [log₂15]=4 bits wide.

The compacted test plan generation method and the test sequence generation method described so far are each implemented using a program for causing a computer to execute prescribed processing. The program may be stored on a hard disk connected to the computer, or may be stored on a storage medium such as a CD-ROM and may be read as needed into an internal storage device within the computer by inserting the CD-ROM in a CD-ROM drive; alternatively, the program may be stored in a storage device connected to a network and may be read as needed into an internal storage device within the computer via the network. The method and apparatus of the invention are thus achieved.

As described above, according to the present invention, the test plans for the circuit elements forming the RTL data path circuit are scheduled in parallel in a form that can be compacted, and are compacted to generate a compacted test plan; as a result, the test sequence length can be drastically reduced, and thus the amount of circuitry to be added for testing purposes can be reduced.

1. A method for generating a compacted test plan for testing an integrated circuit, comprising the steps of:
generating a plurality of test plans, one for each of a plurality of circuit elements contained in an RTL data path circuit; and
compacting said generated plurality of test plans and thereby generating a compacted test plan.

2. A method according to claim 1, wherein said test plan compacting step includes the substeps of:
(a) selecting and extracting one first test plan from a set of test plans;
(b) further selecting and extracting zero or more second test plans from said set of test plans after said substep (a);
(c) compacting said first and second test plans and thereby generating a partly compacted test plan;
(d) repeating said substeps (a) to (c) until said set of test plans becomes an empty set; and
(e) taking a set of said generated partly compacted test plans as a new set of test plans, and repeating said substeps (a) to (d) until the number of partly compacted test plans becomes 1.

3. A method according to claim 2, wherein said test plan compacting step further includes the substeps of:
(f) repeating said substeps (a) to (e) a prescribed number of times by changing an initial condition; and
(g) adopting a compacted test plan having the shortest length from among the compacted test plans obtained by performing said repeating substep (f).

4. A method according to claim 1, wherein said test plan compacting step includes the substeps of:
(a) selecting from among said plurality of test plans a pair of test plans that, when compacted, would yield a partly compacted test plan having the shortest length;
(b) compacting said selected pair of test plans and thereby generating a partly compacted test plan;
(c) selecting from among the test plans remaining uncompacted a test plan that, when compacted with said partly compacted test plan, would yield a partly compacted test plan having the shortest length;
(d) compacting said selected test plan with said partly compacted test plan and thereby generating a partly compacted test plan; and
(e) repeating said substeps (c) and (d) until there is no test plan remaining uncompacted.

5. A method according to claim 1, wherein in said test plan generating step, said test plans are generated for all circuit elements, other than selectors, contained in said RTL data path circuit.

6. A method according to claim 1, further comprising the step of arranging said plurality of test plans into a plurality of groups according to an estimated number of test patterns needed for each of said circuit elements, and wherein
in said test plan compacting step, a compacted test plan is generated for each of said groups by compacting said test plans for said each group.

7. A method for generating a test sequence for testing an integrated circuit, comprising the steps of:
generating a plurality of test plans, one for each of a plurality of circuit elements contained in an RTL data path circuit;
compacting said generated plurality of test plans and thereby generating a compacted test plan;
generating a necessary number of test patterns for each of said plurality of circuit elements contained in said RTL data path circuit; and
generating a test sequence by inserting said test patterns into said compacted test plan.

8. A method according to claim 7, wherein said test plan compacting step includes the substeps of:
(a) selecting and extracting one first test plan from a set of test plans;
(b) further selecting and extracting zero or more second test plans from said set of test plans after said substep (a);
(c) compacting said first and second test plans and thereby generating a partly compacted test plan;
(d) repeating said substeps (a) to (c) until said set of test plans becomes an empty set; and
(e) taking a set of said generated partly compacted test plans as a new set of test plans, and repeating said substeps (a) to (d) until the number of partly compacted test plans becomes 1.

9. A method according to claim 8, wherein said test plan compacting step further includes the substeps of:
(f) repeating said substeps (a) to (e) a prescribed number of times by changing an initial condition; and
(g) adopting a compacted test plan having the shortest length from among the compacted test plans obtained by performing said repeating substep (f).

10. A method according to claim 7, wherein said test plan compacting step includes the substeps of:
(a) selecting from among said plurality of test plans a pair of test plans that, when compacted, would yield a partly compacted test plan having the shortest length;
(b) compacting said selected pair of test plans and thereby generating a partly compacted test plan;
(c) selecting from among the test plans remaining uncompacted a test plan that, when compacted with said partly compacted test plan, would yield a partly compacted test plan having the shortest length;
(d) compacting said selected test plan with said partly compacted test plan and thereby generating a partly compacted test plan; and
(e) repeating said substeps (c) and (d) until there is no test plan remaining uncompacted.

11. A method according to claim 7, wherein in said test plan generating step, said test plans are generated for all circuit elements, other than selectors, contained in said RTL data path circuit.

12. A method according to claim 7, further comprising the step of arranging said plurality of test plans into a plurality of groups according to an estimated number of test patterns needed for each of said circuit elements, and wherein
in said test plan compacting step, a compacted test plan is generated for each of said groups by compacting said test plans for said each group.

13. A method for testing an integrated circuit, comprising the steps of:
generating a plurality of test plans, one for each of a plurality of circuit elements contained in an RTL data path circuit;
compacting said generated plurality of test plans and thereby generating a compacted test plan;
generating a necessary number of test patterns for each of said plurality of circuit elements contained in said RTL data path circuit;
generating a test sequence by inserting said test patterns into said compacted test plan; and
sequentially supplying said generated test sequence to said data path circuit.

14. A method according to claim 13, wherein said test plan compacting step includes the substeps of:
(a) selecting and extracting one first test plan from a set of test plans;
(b) further selecting and extracting zero or more second test plans from said set of test plans after said substep (a);
(c) compacting said first and second test plans and thereby generating a partly compacted test plan;
(d) repeating said substeps (a) to (c) until said set of test plans becomes an empty set; and
(e) taking a set of said generated partly compacted test plans as a new set of test plans, and repeating said substeps (a) to (d) until the number of partly compacted test plans becomes 1.

15. A method according to claim 14, wherein said test plan compacting step further includes the substeps of:
(f) repeating said substeps (a) to (e) a prescribed number of times by changing an initial condition; and
(g) adopting a compacted test plan having the shortest length from among the compacted test plans obtained by performing said repeating substep (f).

16. A method according to claim 13, wherein said test plan compacting step includes the substeps of:
(a) selecting from among said plurality of test plans a pair of test plans that, when compacted, would yield a partly compacted test plan having the shortest length;
(b) compacting said selected pair of test plans and thereby generating a partly compacted test plan;
(c) selecting from among the test plans remaining uncompacted a test plan that, when compacted with said partly compacted test plan, would yield a partly compacted test plan having the shortest length;
(d) compacting said selected test plan with said partly compacted test plan and thereby generating a partly compacted test plan; and
(e) repeating said substeps (c) and (d) until there is no test plan remaining uncompacted.

17. A method according to claim 13, wherein in said test plan generating step, said test plans are generated for all circuit elements, other than selectors, contained in said RTL data path circuit.

18. A method according to claim 13, further comprising the step of arranging said plurality of test plans into a plurality of groups according to an estimated number of test patterns needed for each of said circuit elements, and wherein
in said test plan compacting step, a compacted test plan is generated for each of said groups by compacting said test plans for said each group.

19. A method for generating a test sequence for testing an integrated circuit, comprising the steps of:
generating for each of a plurality of circuit elements contained in an RTL data path circuit the same number of test plans as the number of test patterns needed for each of said circuit elements;
generating a compacted test by compacting said generated test plans; and
generating a test sequence by inserting said test patterns needed for each of said circuit elements into said compacted test.

20. A method for generating a compacted test plan for testing an integrated circuit, comprising the steps of:
generating a first plurality of test plans, one for each of a plurality of circuit elements contained in an RTL data path in a first circuit block contained in an RTL circuit;
generating a second plurality of test plans, one for each of a plurality of circuit elements contained in an RTL data path in a second circuit block contained in said RTL circuit; and
compacting said first and second pluralities of test plans and thereby generating one compacted test plan.

21. A method for testing an integrated circuit, comprising the steps of:
generating a first plurality of test plans, one for each of a plurality of circuit elements contained in an RTL data path in a first circuit block contained in an RTL circuit;
generating a second plurality of test plans, one for each of a plurality of circuit elements contained in an RTL data path in a second circuit block contained in said RTL circuit;
compacting said first and second pluralities of test plans and thereby generating one compacted test plan;
generating a necessary number of test patterns for each of said circuit elements contained in said first and second circuit blocks;
generating a test sequence by inserting said test patterns into said compacted test plan; and
sequentially supplying said test sequence to said data path circuit.

22. An apparatus for generating a compacted test plan for testing an integrated circuit, comprising:
means for generating a plurality of test plans, one for each of a plurality of circuit elements contained in an RTL data path circuit; and
means for compacted said generated plurality of test plans and thereby generating a compacted test plan.

23. An apparatus according to claim 22, wherein said test plan compacting means includes:
first means for selecting and extracting one first test plan from a set of test plans;
second means for selecting and extracting zero or more second test plans from said set of test plans after said first test plan extracting means has extracted said first test plan;
means for compacting said first and second test plans and thereby generating a partly compacted test plan;
first means for repeating operation of said first and second test plan extracting mean and said partly compacted test plan generating means until said set of test plans becomes an empty set; and
second means for taking a set of said generated partly compacted test plans as a new set of test plans, and for repeating operation of said first and second test plan extracting mean, said partly compacted test plan generating means, and said first repeating means until the number of partly compacted test plans becomes 1.

24. An apparatus according to claim 23, wherein said test plan compacting means further includes:
third means for repeating operation of said first and second test plan extracting mean, said partly compacted test plan generating means, and said first and second repeating means a prescribed number of times by changing an initial condition; and
means for adopting a compacted test plan having the shortest length from among the compacted test plans obtained by performing the repeating operation of said third repeating means.

25. An apparatus according to claim 22, wherein said test plan compacting means includes:
first means for selecting from among said plurality of test plans a pair of test plans that, when compacted, would yield a partly compacted test plan having the shortest length;
first means for compacting said selected pair of test plans and thereby generating a partly compacted test plan;
second means for selecting, from among the test plans remaining uncompacted, a test plan that, when compacted with said partly compacted test plan, would yield a partly compacted test plan having the shortest length;
second means for compacting said selected test plan with said partly compacted test plan and thereby generating a partly compacted test plan; and
means for repeating operation of said second selecting means and said second generating means until there is no test plan remaining uncompacted.

26. An apparatus according to claim 22, wherein said test plan generating means generates said test plans for all circuit elements, other than selectors, contained in said RTL data path circuit.

27. An apparatus according to claim 22, further comprising means for arranging said plurality of test plans into a plurality of groups according to an estimated number of test patterns needed for each of said circuit elements, and wherein
said test plan compacting means generates a compacted test plan for each of said groups by compacting said test plans for said each group.

28. An apparatus for generating a test sequence for testing an integrated circuit, comprising:
means for generating a plurality of test plans, one for each of a plurality of circuit elements contained in an RTL data path circuit;
means for compacting said generated plurality of test plans and thereby generating a compacted test plan;
means for generating a necessary number of test patterns for each of said plurality of circuit elements contained in said RTL data path circuit; and
means for generating a test sequence by inserting said test patterns into said compacted test plan.

29. An apparatus according to claim 28, wherein said test plan compacting means includes:
first means for selecting and extracting one first test plan from a set of test plans;
second means for selecting and extracting zero or more second test plans from said set of test plans after said first test plan extracting means has extracted said first test plan;
means for compacting said first and second test plans and thereby generating a partly compacted test plan;
first means for repeating operation of said first and second test plan extracting mean and said partly compacted test plan generating means until said set of test plans becomes an empty set; and
second means for taking a set of said generated partly compacted test plans as a new set of test plans, and for repeating operation of said first and second test plan extracting mean, said partly compacted test plan generating means, and said first repeating means until the number of partly compacted test plans becomes 1.

30. An apparatus according to claim 29, wherein said test plan compacting means further includes:
third means for repeating operation of said first and second test plan extracting mean, said partly compacted test plan generating means, and said first and second repeating means a prescribed number of times by changing an initial condition; and
means for adopting a compacted test plan having the shortest length from among the compacted test plans obtained by performing the repeating operation of said third repeating means.

31. An apparatus according to claim 28, wherein said test plan compacting means includes:
first means for selecting from among said plurality of test plans a pair of test plans that, when compacted, would yield a partly compacted test plan having the shortest length;
first means for compacting said selected pair of test plans and thereby generating a partly compacted test plan;
second means for selecting from among the test plans remaining uncompacted a test plan that, when compacted with said partly compacted test plan, would yield a partly compacted test plan having the shortest length;
second means for compacting said selected test plan with said partly compacted test plan and thereby generating a partly compacted test plan; and
means for repeating operation of said second selecting means and said second generating means until there is no test plan remaining uncompacted.

32. An apparatus according to claim 28, wherein said test plan generating means generates said test plans for all circuit elements, other than selectors, contained in said RTL data path circuit.

33. An apparatus according to claim 28, further comprising means for arranging said plurality of test plans into a plurality of groups according to an estimated number of test patterns needed for each of said circuit elements, and wherein
said test plan compacting means generates a compacted test plan for each of said groups by compacting said test plans for said each group.

34. An integrated circuit equipped with a test function, comprising:
a data path circuit to be tested; and
a test controller for sequentially supplying a test sequence to said data path circuit, said test sequence being generated by inserting test patterns needed for each of a plurality of circuit elements contained in said data path circuit into a compacted test plan generated by compacting a plurality of test plans generated one for each of said plurality of circuit elements.

35. An apparatus for generating a test sequence for testing an integrated circuit, comprising:
means for generating for each of a plurality of circuit elements contained in an RTL data path circuit the same number of test plans as the number of test patterns needed for each of said circuit elements;
means for generating a compacted test by compacting said generated test plans; and
means for generating a test sequence by inserting said test patterns needed for each of said circuit elements into said compacted test.

36. An apparatus for generating a compacted test plan for testing an integrated circuit, comprising:
means for generating a first plurality of test plans, one for each of a plurality of circuit elements contained in an RTL data path in a first circuit block contained in an RTL circuit;
means for generating a second plurality of test plans, one for each of a plurality of circuit elements contained in an RTL data path in a second circuit block contained in said RTL circuit; and
means for compacting said first and second pluralities of test plans and thereby generating one compacted test plan.

37. An integrated circuit equipped with a test function, comprising:
a data path circuit to be tested; and
a test controller for sequentially supplying a test sequence to said data path circuit, said test sequence being generated by inserting test patterns into a compacted test in quantities needed for each of a plurality of circuit elements contained in a first circuit block and a second circuit block, wherein said first and second circuit blocks are contained in said data path circuit and said compacted test plan is generated by compacting a first plurality of test plans, generated one for each of said plurality of circuit elements contained in an RTL data path in said first circuit block, and a second plurality of test plans, generated one for each of said plurality of circuit elements contained in an RTL data path in said second circuit block.

38. A program storage device readable by a machine, tangibly embodying a program of instructions executable by the machine to perform method steps for generating a compacted test plan, said method steps comprising:
generating a plurality of test plans, one for each of a plurality of circuit elements contained in an RTL data path circuit; and
compacting said generated plurality of test plans and thereby generating a compacted test plan.

39. A program storage device according to claim 38, wherein said test plan compacting step includes the substeps of:
(a) selecting and extracting one first test plan from a set of test plans;
(b) further selecting and extracting zero or more second test plans from said set of test plans after said substep (a);
(c) compacting said first and second test plans and thereby generating a partly compacted test plan;
(d) repeating said substeps (a) to (c) until said set of test plans becomes an empty set; and
(e) taking a set of said generated partly compacted test plans as a new set of test plans, and repeating said substeps (a) to (d) until the number of partly compacted test plans becomes 1.

40. A program storage device according to claim 39, wherein said test plan compacting step further includes the substeps of:
(f) repeating said substeps (a) to (e) a prescribed number of times by changing an initial condition; and
(g) adopting a compacted test plan having the shortest length from among the compacted test plans obtained by performing said repeating substep (f).

41. A program storage device according to claim 38, wherein said test plan compacting step includes the substeps of:
(a) selecting from among said plurality of test plans a pair of test plans that, when compacted, would yield a partly compacted test plan having the shortest length;
(b) compacting said selected pair of test plans and thereby generating a partly compacted test plan;
(c) selecting from among the test plans remaining uncompacted a test plan that, when compacted with said partly compacted test plan, would yield a partly compacted test plan having the shortest length;
(d) compacting said selected test plan with said partly compacted test plan and thereby generating a partly compacted test plan; and
(e) repeating said substeps (c) and (d) until there is no test plan remaining uncompacted.

42. A program storage device according to claim 38, wherein in said test plan generating step, said test plans are generated for all circuit elements, other than selectors, contained in said RTL data path circuit.

43. A program storage device according to claim 38, further comprising the step of arranging said plurality of test plans into a plurality of groups according to an estimated number of test patterns needed for each of said circuit elements, and wherein
in said test plan compacting step, a compacted test plan is generated for each of said groups by compacting said test plans for said each group.

44. A program storage device readable by a machine, tangibly embodying a program of instructions executable by the machine to perform method steps for generating a test sequence for testing an integrated circuit, said method steps comprising:
generating a plurality of test plans, one for each of a plurality of circuit elements contained in an RTL data path circuit;
compacting said generated plurality of test plans and thereby generating a compacted test plan;
generating a necessary number of test patterns for each of said plurality of circuit elements contained in said RTL data path circuit; and
generating a test sequence by inserting said test patterns into said compacted test plan.

45. A program storage device according to claim 44, wherein said test plan compacting step includes the substeps of:
(a) selecting and extracting one first test plan from a set of test plans;
(b) further selecting and extracting zero or more second test plans from said set of test plans after said substep (a);
(c) compacting said first and second test plans and thereby generating a partly compacted test plan;
(d) repeating said substeps (a) to (c) until said set of test plans becomes an empty set; and
(e) taking a set of said generated partly compacted test plans as a new set of test plans, and repeating said substeps (a) to (d) until the number of partly compacted test plans becomes 1.

46. A program storage device according to claim 45, wherein said test plan compacting step further includes the substeps of:
(f) repeating said substeps (a) to (e) a prescribed number of times by changing an initial condition; and
(g) adopting a compacted test plan having the shortest length from among the compacted test plans obtained by performing said repeating substep (f).

47. A program storage device according to claim 44, wherein said test plan compacting step includes the substeps of:
(a) selecting from among said plurality of test plans a pair of test plans that, when compacted, would yield a partly compacted test plan having the shortest length;
(b) compacting said selected pair of test plans and thereby generating a partly compacted test plan;
(c) selecting from among the test plans remaining uncompacted a test plan that, when compacted with said partly compacted test plan, would yield a partly compacted test plan having the shortest length;
(d) compacting said selected test plan with said partly compacted test plan and thereby generating a partly compacted test plan; and
(e) repeating said substeps (c) and (d) until there is no test plan remaining uncompacted.

48. A program storage device according to claim 44, wherein in said test plan generating step, said test plans are generated for all circuit elements, other than selectors, contained in said RTL data path circuit.

49. A program storage device according to claim 44, further comprising the step of arranging said plurality of test plans into a plurality of groups according to an estimated number of test patterns needed for each of said circuit elements, and wherein
in said test plan compacting step, a compacted test plan is generated for each of said groups by compacting said test plans for said each group.

50. A program storage device readable by a machine, tangibly embodying a program of instructions executable by the machine to perform method steps for generating a test sequence for testing an integrated circuit, said method steps comprising:
generating for each of a plurality of circuit elements contained in an RTL data path circuit the same number of test plans as the number of test patterns needed for each of said circuit elements;
generating a compacted test by compacting said generated test plans; and
generating a test sequence by inserting said test patterns needed for each of said circuit elements into said compacted test.

51. A program storage device readable by a machine, tangibly embodying a program of instructions executable by the machine to perform method steps for generating a test sequence for testing an integrated circuit, said method steps comprising:
generating a first plurality of test plans, one for each of a plurality of circuit elements contained in an RTL data path in a first circuit block contained in an RTL circuit;
generating a second plurality of test plans, one for each of a plurality of circuit elements contained in an RTL data path in a second circuit block contained in said RTL circuit; and
compacting said first and second pluralities of test plans and thereby generating one compacted test plan.
